(19) United States
(12) Patent Application Publication
(10) Pub. No.: US 2026/0040871 A1
(43) Pub. Date: Feb. 5, 2026

(54) SUBSTRATE POLISHING APPARATUS

(71) Applicant: SAMSUNG ELECTRONICS CO., LTD., Suwon-si (KR)

(72) Inventors: Donghoon Kwon, Suwon-si (KR); Jaeyoung Bae, Suwon-si (KR)

(21) Appl. No.: 19/019,172

(22) Filed: Jan. 13, 2025

(30) Foreign Application Priority Data
Aug. 1, 2024 (KR) 10-2024-0102706

(51) Int. Cl. H01L 21/67; B08B 1/12; B08B 1/34; B08B 3/02; B08B 3/04; B08B 3/08; B08B 5/02; B24B 37/34

(52) U.S. Cl. CPC H01L 21/67219; B08B 1/12; B08B 1/34; B08B 3/022; B08B 3/024; B08B 3/041; B08B 3/08; B08B 5/023; B24B 37/345; H01L 21/67051

(57) ABSTRACT

An example substrate polishing apparatus includes a polishing unit, a cleaning unit, and a standby unit. The polishing unit includes a plurality of polishing modules defining a first space and being configured to perform a polishing process on a substrate. The cleaning unit includes a plurality of cleaning modules defining a second space and being configured to perform a cleaning process on the substrate. The standby unit includes a buffer unit between the polishing unit and the cleaning unit in a first horizontal direction and defining a third space that accommodates the substrate. The standby unit includes a plurality of coating modules defining a fourth space and being configured to form a coating layer on a front surface of the substrate. The polishing module includes a polishing pad configured to contact a rear surface of the substrate opposite to the front surface.

### CROSS-REFERENCE TO RELATED APPLICATION

This application claims priority under 35 U.S.C. § 119 to Korean Patent Application No. 10-2024-0102706, filed on Aug. 1, 2024, in the Korean Intellectual Property Office, the disclosure of which is incorporated by reference herein in its entirety.

### BACKGROUND

There are various surface planarization technologies for planarizing the surface of a substrate; however, among them, a chemical mechanical polishing (CMP) device is mainly used because the CMP device may achieve an excellent surface flatness not only in narrow-area planarization but also in wide-area planarization. The CMP device is used to polish the surface of a substrate by mechanical friction and simultaneously by a chemical abrasive, thus enabling very fine polishing.

### SUMMARY

The present disclosure relates to a substrate polishing apparatus with improved reliability.

The problems to be solved by the present disclosure are not limited to the problems mentioned above, and other unmentioned problems will be clearly understood by those of ordinary skill in the art from the following description.

In general, according to some aspects, a substrate polishing apparatus includes a polishing unit including a plurality of polishing modules providing a space for performing a polishing process on a substrate, a cleaning unit including a plurality of cleaning modules providing a space for performing a cleaning process on the substrate, and a standby unit including a buffer unit arranged between the polishing unit and the cleaning unit in a first horizontal direction to provide a space for accommodating the substrate, wherein the standby unit further includes a plurality of coating modules providing a space for forming a coating layer on a front surface of the substrate, and the polishing module includes a polishing pad configured to contact a rear surface of the substrate opposite to the front surface of the substrate with the coating layer formed thereon.

In general, according to some aspects, a substrate polishing apparatus includes a polishing unit including a plurality of polishing modules providing a space for performing a polishing process on a substrate, and a cleaning unit including a plurality of cleaning modules providing a space for performing a cleaning process on the substrate, wherein the cleaning unit further includes a plurality of coating modules providing a space for forming a coating layer on a front surface of the substrate, and a plurality of coating removing modules providing a space for removing the coating layer formed on the front surface of the substrate, and the polishing module includes a polishing pad configured to contact a rear surface of the substrate opposite to the front surface with the coating layer formed thereon.

In general, according to some aspects, a substrate polishing apparatus includes a polishing unit including a plurality of polishing modules providing a space for performing a polishing process on a substrate, a cleaning unit including a plurality of cleaning modules providing a space for performing a cleaning process on the substrate, and a standby unit including a buffer unit arranged between the polishing unit and the cleaning unit in a first horizontal direction to provide a space for accommodating the substrate, wherein the polishing unit further includes a first transfer module located between the buffer unit and the polishing module and configured to provide a movement path for the substrate between the buffer unit and the plurality of polishing modules, the standby unit further includes a pair of coating modules providing a space for forming a coating layer on a front surface of the substrate and arranged apart from each other in a second horizontal direction perpendicular to the first horizontal direction, the cleaning unit further includes a pair of coating removing modules providing a space for removing the coating layer formed on the front surface of the substrate and arranged apart from each other in the second horizontal direction, and the polishing module includes a polishing pad configured to contact a rear surface of the substrate opposite to the front surface with the coating layer formed thereon.

### BRIEF DESCRIPTION OF THE DRAWINGS

Implementations will be more clearly understood from the following detailed description taken in conjunction with the accompanying drawings.

FIG. 1A is a plan view of an example of a substrate polishing apparatus, and FIG. 1B is a plan view of an example of a substrate polishing apparatus.

FIG. 2A is a plan view of an example of a substrate polishing apparatus, and FIG. 2B is a plan view of an example of a substrate polishing apparatus.

FIG. 3A is a plan view of an example of a substrate polishing apparatus, and FIG. 3B is a plan view of an example of a substrate polishing apparatus.

FIG. 4A is a plan view of an example of a substrate polishing apparatus, and FIGS. 4B, 4C, and 4D are plan views of an example of a substrate polishing apparatus.

FIG. 5 is a flowchart of an example of a control method of a substrate polishing apparatus.

FIG. 6 is a block diagram of an example of a substrate polishing apparatus.

FIGS. 7A to 7F are cross-sectional views sequentially illustrating some of the processes of an example of a control method of a substrate polishing apparatus.

FIGS. 8A and 8B are cross-sectional views sequentially illustrating some of the processes of an example of a control method of a substrate polishing apparatus.

FIGS. 9A to 9D are cross-sectional views sequentially illustrating some of the processes of an example of a control method of a substrate polishing apparatus.

FIGS. 10A and 10B are cross-sectional views sequentially illustrating some of the processes of an example of a control method of a substrate polishing apparatus.

FIGS. 11A to 11C are cross-sectional views sequentially illustrating some of the processes of an example of a control method of a substrate polishing apparatus.

FIG. 12 is a plan view of an example of a polishing module included in a substrate polishing apparatus.

FIGS. 13A and 13B are cross-sectional views sequentially illustrating some of the processes of an example of a control method of a substrate polishing apparatus.

FIGS. 14A to 14F are cross-sectional views sequentially illustrating some of the processes of an example of a control method of a substrate polishing apparatus.

FIGS. 15 and 16 are cross-sectional views sequentially illustrating some of the processes of an example of a control method of a substrate polishing apparatus.

### DETAILED DESCRIPTION

Hereinafter, implementations will be described in detail with reference to the accompanying drawings. Herein, like reference numerals will denote like elements, and redundant descriptions thereof will be omitted for conciseness.

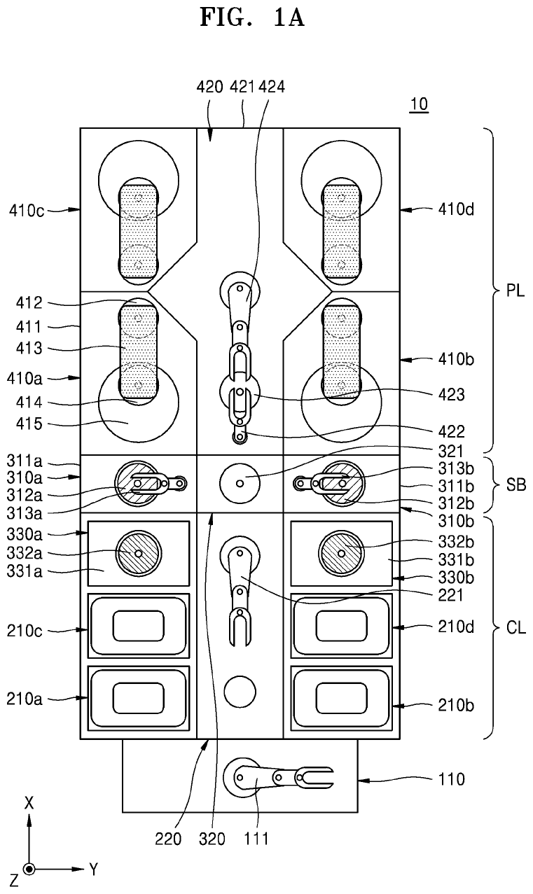

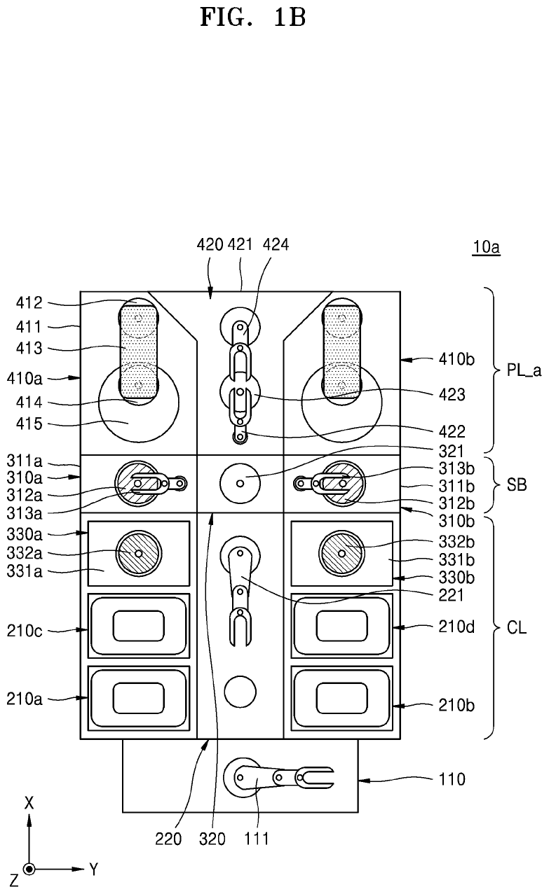

FIG. 1A is a plan view of an example of a substrate polishing apparatus 10, and FIG. 1B is a plan view of an example of a substrate polishing apparatus 10a.

Referring to FIG. 1, the substrate polishing apparatus 10 may include an index module 110, a cleaning unit CL, a standby unit SB, and a polishing unit PL.

The index module 110 may provide a space in which a cassette with substrates stored therein is located. The index module 110 may unload substrates from a cassette and transfer the unloaded substrates to an index module robot arm 111 or may load a substrate on which a polishing process has been completed into a cassette.

The cleaning unit CL may be arranged between the index module 110 and the standby unit SB. The cleaning unit CL may include first to fourth cleaning modules 210a to 210d, a first coating removing module 330a, a second coating removing module 330b, a first transfer module 220, and a first transfer module robot arm 221.

The first cleaning module 210a may be arranged to face the second cleaning module 210b with the first transfer module 220 therebetween, and the third cleaning module 210c may be arranged to face the fourth cleaning module 210d with the first transfer module 220 therebetween. Also, the first coating removing module 330a and the second coating removing module 330b may be arranged to face each other with the first transfer module 220 therebetween. Herein, a direction in which the cleaning unit CL, the standby unit SB, and the polishing unit PL are arranged in parallel may be defined as a first horizontal direction (X direction). Also, a direction which is perpendicular to the first horizontal direction (X direction) in FIGS. 1A and 1n which the first coating removing module 330a and the second coating removing module 330b are spaced apart from each other in parallel may be defined as a second horizontal direction (Y direction). Also, a direction perpendicular to both the first horizontal direction (X direction) and the second horizontal direction (Y direction) may be defined as a vertical direction (Z direction).

In the substrate polishing apparatus 10, the polished substrate may be arranged on a buffer unit load cup 321 of a buffer unit 320 described below. The first transfer module 220 may transfer the polished substrate to the first to fourth cleaning modules 210a to 210d or to the first and second coating removing modules 330a and 330b. Particularly, the substrate arranged on the buffer unit load cup 321 may be transferred to the first and second coating removing modules 330a and 330b by the first transfer module robot arm 221 of the first transfer module 220 arranged adjacent to the buffer unit load cup 321. The substrate from which a coating layer has been removed may then be transferred to the first to fourth cleaning modules 210a to 210d by the first transfer module robot arm 221. The first and second coating removing modules 330a and 330b may be configured to remove a coating layer formed on the front surface of a substrate, which will be described below.

The first to fourth cleaning modules 210a to 210d may clean off the contaminants remaining on the polished substrate. The cleaned substrate may be returned to the index module 110 and stored in the cassette. Accordingly, the polishing process on the substrate may be completed.

The standby unit SB may include first and second coating modules 310a and 310b and the buffer unit 320. The first and second coating modules 310a and 310b may be arranged apart from each other with the buffer unit 320 therebetween in the second horizontal direction (Y direction). The first and second coating modules 310a and 310b may be configured to form a coating layer on the front surface of a substrate, which will be described below. Herein, the front surface of the substrate may refer to a surface of the substrate on which a semiconductor device is formed.

The first coating module 310a may include a first coating chamber 311a, a first substrate support 312a, and a first coating module robot arm 313a, and the second coating module 310b may include a second coating chamber 311b, a second substrate support 312b, and a second coating module robot arm 313b.

In some implementations, the first coating chamber 311a may provide a space for performing a coating process of forming a coating layer on the front surface of the substrate. The first substrate support 312a may be arranged in the first coating chamber 311a to support the substrate so that a coating layer may be formed on the front surface of the substrate. The first coating module robot arm 313a may be arranged in the first coating chamber 311a and configured to load a substrate waiting in the buffer unit 320 into the first coating chamber 311a and seat the substrate on the first substrate support 312a. The first coating chamber 311a may include a path through which the substrate seated on the buffer unit load cup 321 may be loaded/unloaded.

In some implementations, the second coating module 310b may also perform the same function as the first coating module 310a. The second coating chamber 311b may provide a space for performing a coating process of forming a coating layer on the front surface of the substrate. The second substrate support 312b may be arranged in the second coating chamber 311b to support the substrate so that a coating layer may be formed on the front surface of the substrate. The second coating module robot arm 313b may be arranged in the second coating chamber 311b and configured to load a substrate waiting in the buffer unit 320 into the second coating chamber 311b and seat the substrate on the second substrate support 312b. The second coating chamber 311b may include a path through which the substrate seated on the buffer unit load cup 321 may be loaded/unloaded.

The first coating removing module 330a may include a first coating removing chamber 331a and a third substrate support 332a, and the second coating removing module 330b may include a second coating removing chamber 331b and a fourth substrate support 332b.

In some implementations, the first coating removing chamber 331a may provide a space for performing a process of removing a coating layer formed on the front surface of the substrate. The third substrate support 332a may be arranged in the first coating removing chamber 331a to support the substrate so that the coating layer formed on the front surface of the substrate may be removed. The first transfer module robot arm 221 may be arranged in the first transfer module 220 and configured to load a substrate waiting on the buffer unit load cup 321 into the first coating removing chamber 331a and seat the substrate on the third substrate support 332a. The first coating removing chamber 331a may include a path through which the substrate seated on the buffer unit load cup 321 may be loaded/unloaded.

In some implementations, the second coating removing module 330b may also perform the same function as the first coating removing module 330a. The second coating removing chamber 331b may provide a space for performing a process of removing the coating layer formed on the front surface of the substrate. The fourth substrate support 332b may be arranged in the second coating removing chamber 331b to support the substrate so that the coating layer formed on the front surface of the substrate may be removed. The first transfer module robot arm 221 may be arranged in the first transfer module 220 and configured to load a substrate waiting on the buffer unit load cup 321 into the second coating removing chamber 331b and seat the substrate on the fourth substrate support 332b. The second coating removing chamber 331b may include a path through which the substrate seated on the buffer unit load cup 321 may be loaded/unloaded.

In some implementations, the first coating module 310a and the second coating module 310b may be included in the standby unit SB located between the cleaning unit CL and the polishing unit PL. Because the first coating module 310a and the second coating module 310b are located in the standby unit SB, a coating layer forming process may be preliminarily performed before the substrate is loaded into a second transfer module 420 to perform a polishing process on the substrate.

Also, the first coating removing module 330a and the second coating removing module 330b may be included in the cleaning unit CL where the first to fourth cleaning modules 210a to 210d are located. Because the first coating removing module 330a and the second coating removing module 330b are located in the cleaning unit CL, the contaminants remaining in the cleaning module may be immediately cleaned off after the coating layer formed on the front surface of the substrate on which the polishing process has been completed is removed by the coating removing module.

The polishing unit PL may include first to fourth polishing modules 410a to 410d and a second transfer module 420. Because all of the first to fourth polishing modules 410a to 410d may be configured to perform chemical mechanical polishing (CMP) in the same manner, the description will focus on the first polishing module 410a.

The first polishing module 410a may include a polishing chamber 411, a loading unit 412, a polishing head support unit 413, a polishing head 414, and a polishing pad 415. The polishing chamber 411 may provide a space in which the loading unit 412, the polishing head support unit 413, the polishing head 414, and the polishing pad 415 may be included. The loading unit 412, the polishing head support unit 413, the polishing head 414, and the polishing pad 415 will be described below in detail. The polishing chamber 411 may provide a path through which a second transfer module robot arm 424 may enter and seat the substrate seated on a second transfer module substrate holder 423 in the second transfer module 420.

In some implementations, the second transfer module 420 may include a second transfer chamber 421, a second transfer module exchanger 422, a second transfer module substrate holder 423, and a second transfer module robot arm 424.

The second transfer chamber 421 may provide a space in which the second transfer module exchanger 422, the second transfer module substrate holder 423, and the second transfer module robot arm 424 may be included. A path through which the substrate may be loaded/unloaded through the first to fourth polishing modules 410a to 410d and a path through which the substrate may be loaded/unloaded through the buffer unit 320 may be formed around the second transfer chamber 421. The second transfer module exchanger 422 may be configured to transfer the substrate seated on the buffer unit load cup 321 to the second transfer module substrate holder 423 through the path formed around the second transfer chamber 421. The second transfer module substrate holder 423 may provide a space in which the substrate temporarily waits in the second transfer module 420. The second transfer module robot arm 424 may be configured to transfer the substrate waiting in the second transfer module substrate holder 423 to the first to fourth polishing modules 410a to 410d through the path formed around the second transfer chamber 421. Particularly, the second transfer module robot arm 424 may seat the substrate waiting in the second transfer module substrate holder 423 onto the loading unit 412 of the first polishing module 410a.

FIG. 1B illustrates the substrate polishing apparatus 10a. The substrate polishing apparatus 10a illustrated in FIG. 1B may be substantially the same as or similar to the substrate polishing apparatus 10 illustrated in FIG. 1A, except that the number of polishing modules is different therefrom. Thus, redundant descriptions of the components already mentioned with reference to FIG. 1A will be omitted for conciseness.

The substrate polishing apparatus 10a illustrated in FIG. 1B may include a polishing unit PL_a arranged apart from a cleaning unit CL in the first horizontal direction (X direction) with a standby unit SB therebetween. Unlike the polishing unit PL illustrated in FIG. 1A, the polishing unit PL_a illustrated in FIG. 1B may include two polishing modules, that is, a first polishing module 410a and a second polishing module 410b. The first polishing module 410a and the second polishing module 410b may be located apart from each other in the second horizontal direction (Y direction) with a second transfer module 420 therebetween.

Because only two polishing modules are arranged in the polishing unit PL_a, the length of the substrate polishing apparatus 10a in the first horizontal direction (X direction) may be reduced. Thus, the spatial efficiency of the substrate polishing apparatus 10a may be promoted.

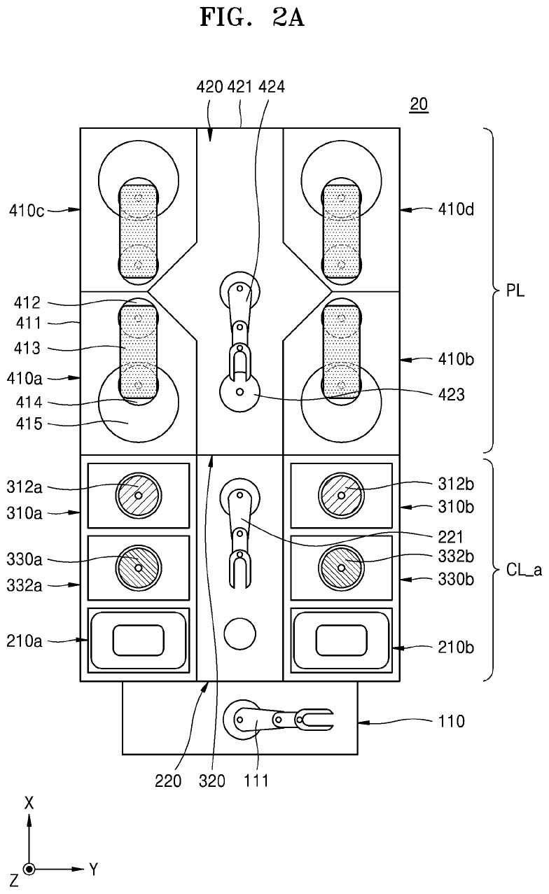

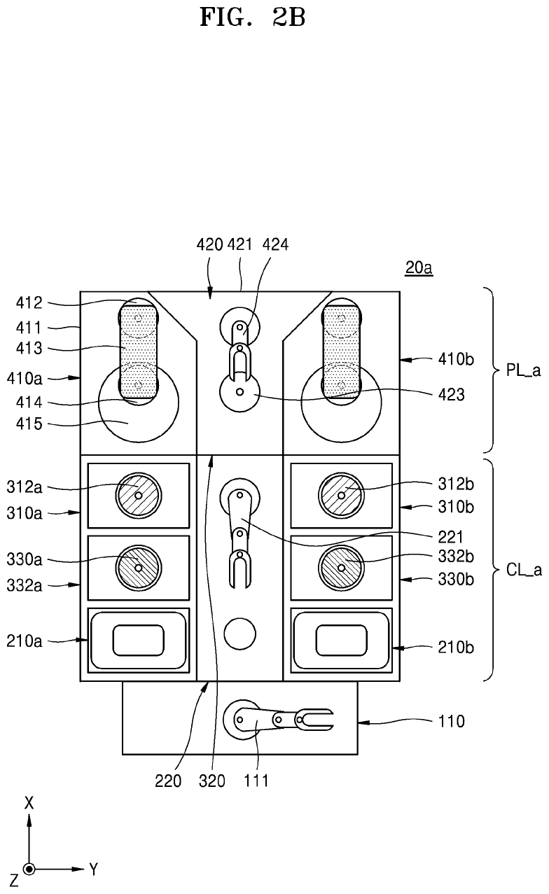

FIG. 2A is a plan view of an example of a substrate polishing apparatus 20, and FIG. 2B is a plan view of an example of a substrate polishing apparatus 20a.

The substrate polishing apparatuses 20 and 20a illustrated in FIGS. 2A and 2B may be substantially the same as or similar to the substrate polishing apparatuses 10 and 10a illustrated in FIGS. 1A and 1B, except that they do not include the standby unit SB (see FIGS. 1A and 1B). Thus, redundant descriptions of the components already mentioned with reference to FIGS. 1A and 1B will be omitted or simplified for conciseness.

Referring to FIG. 2A, the substrate polishing apparatus 20 may include an index module 110, a cleaning unit CL_a, and a polishing unit PL.

The cleaning unit CL_a may be arranged between the index module 110 and the polishing unit PL. The cleaning unit CL_a may include first and second cleaning modules 210a and 210b, first and second coating modules 310a and 310b, and first and second coating removing modules 330a and 330b.

The first coating module 310a and the second coating module 310b may be arranged apart from each other with a first transfer module 220 therebetween. Unlike the substrate polishing apparatus 10 illustrated in FIG. 1A, in the case of the substrate polishing apparatus 20 illustrated in FIG. 2A, the first coating module 310a and the second coating module 310b may be arranged in the cleaning unit CL_a of the substrate polishing apparatus 20. Because the first coating module 310a and the second coating module 310b are arranged in the cleaning unit CL_a, the substrate polishing apparatus 20 may not include the standby unit SB (see FIG. 1).

In the substrate polishing apparatus 20, a first transfer module robot arm 221 of the first transfer module 220 may be configured to transfer the substrate received from the index module 110 to the first coating module 310a or the second coating module 310b. Particularly, the first transfer module robot arm 221 may be configured to seat the substrate received from an index module robot arm 111 on a first substrate support 312a or a second substrate support 312b through a path formed in a first coating chamber 311a or a second coating chamber 311b.

The substrate on which a coating forming process has been completed in the first coating module 310a or the second coating module 310b may then be unloaded from the first transfer module robot arm 221 and transferred to a second transfer module substrate holder 423 of a second transfer module 420. The substrate transferred to the second transfer module substrate holder 423 may then be transferred to first to fourth polishing modules 410a to 410d by a second transfer module robot arm 424 to perform a polishing process. In this case, the second transfer module robot arm 424 may seat the substrate on a loading unit 412 of a plurality of polishing modules 410a to 410d through a path formed in a polishing chamber 411.

The substrate on which a polishing process has been completed may be seated on the second transfer module substrate holder 423 of the second transfer module 420 by the second transfer module robot arm 424. Thereafter, the first transfer module robot arm 221 may collect the substrate seated on the second transfer module substrate holder 423 and load the collected substrate into the first transfer module 220. The substrate loaded into the first transfer module 220 may be transported by the first transfer module robot arm 221 and loaded into the first coating removing module 330a or the second coating removing module 330b. Particularly, the first transfer module robot arm 221 may be seated on a third substrate support 332a included in the first coating removing module 330a or on a fourth substrate support 332b included in the second coating removing module 330b. The substrate seated on the third substrate support 332a or the fourth substrate support 332b may then be subjected to a coating layer removing process in the first coating removing module 330a and the second coating removing module 330b.

The substrate polishing apparatus 20a illustrated in FIG. 2B may be substantially the same as or similar to the substrate polishing apparatus 20 illustrated in FIG. 2A, except that the number of polishing modules is different therefrom. Thus, redundant descriptions of the components already mentioned with reference to FIG. 2A will be omitted for conciseness.

Referring to FIG. 2B, the substrate polishing apparatus 20a may include a polishing unit PL_a arranged apart from a cleaning unit CL_a in the first horizontal direction (X direction). Unlike the polishing unit PL illustrated in FIG. 2A, the polishing unit PL_a illustrated in FIG. 2B may include two polishing modules, that is, a first polishing module 410a and a second polishing module 410b. The first polishing module 410a and the second polishing module 410b may be located apart from each other in the second horizontal direction (Y direction) with a second transfer module 420 therebetween.

Because only two polishing modules are arranged in the polishing unit PL_a, the length of the substrate polishing apparatus 20a in the first horizontal direction (X direction) may be reduced. Thus, the spatial efficiency of the substrate polishing apparatus 20a may be promoted.

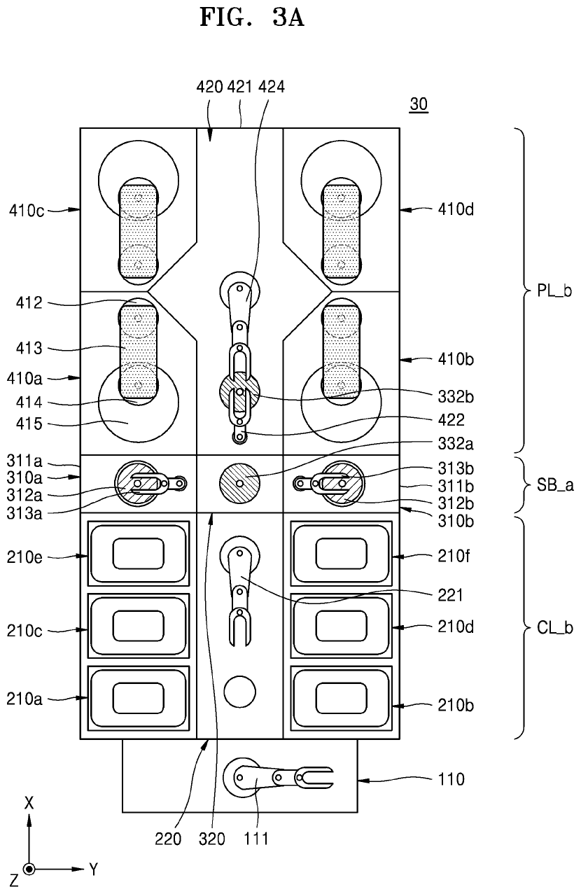

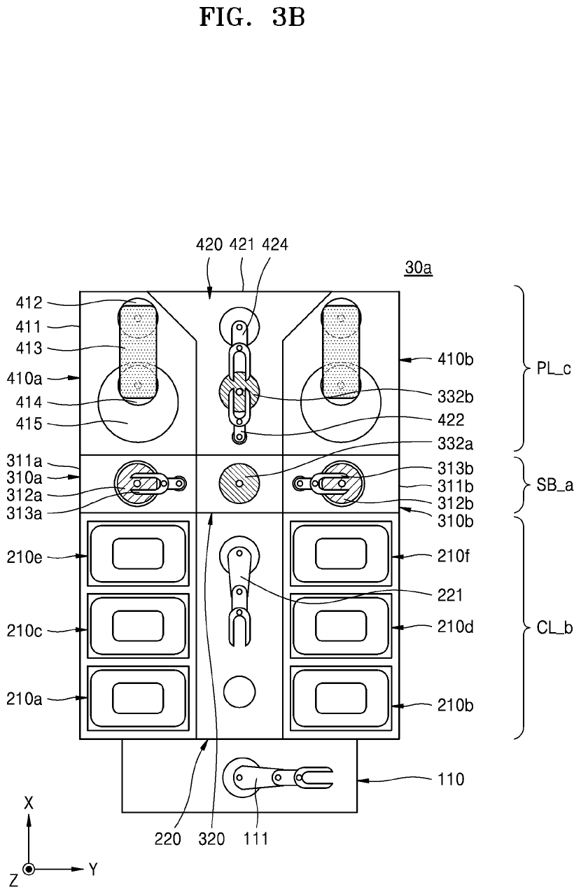

FIG. 3A is a plan view of an example of a substrate polishing apparatus 30, and FIG. 3B is a plan view of an example of a substrate polishing apparatus 30a.

The substrate polishing apparatuses 30 and 30a illustrated in FIGS. 3A and 3B may be substantially the same as or similar to the substrate polishing apparatuses 10 and 10a illustrated in FIGS. 1A and 1B, except that the position of the third substrate support 332a and the fourth substrate support 332b on which a coating removing process is performed is different therefrom. Thus, redundant descriptions of the components already mentioned with reference to FIGS. 1A and 1B will be omitted or simplified for conciseness.

Referring to FIG. 3A, the substrate polishing apparatus 30 may include an index module 110, a cleaning unit CL_b, a standby unit SB_a, and a polishing unit PL_b.

The cleaning unit CL_b arranged between the index module 110 and the standby unit SB_a may include first to sixth cleaning modules 210a to 210f.

The first cleaning module 210a and the third cleaning module 210c may be respectively arranged to face the second cleaning module 210b and the fourth cleaning module 210d with a first transfer module 220 therebetween. Also, the cleaning unit CL_b of the substrate polishing apparatus 30 may include the fifth cleaning module 210e and the sixth cleaning module 210f that are arranged to face each other and arranged apart from each other in the second horizontal direction (Y direction) with the first transfer module 220 therebetween.

In some implementations, the standby unit SB_a of the substrate polishing apparatus 30 illustrated in FIG. 3A may include a third substrate support 332a in a buffer unit 320, instead of the buffer unit load cup 321, as compared to the standby unit SB_a of the substrate polishing apparatus 10 illustrated in FIG. 1A. The third substrate support 332a may be located between a first transfer module 220 and a second transfer module 420 in the first horizontal direction (X direction) and between a first coating module 310a and a second coating module 310b in the second horizontal direction (Y direction).

In some implementations, the third substrate support 332a may provide a space in which a coating layer removing process is performed on the substrate and may simultaneously provide a space in which the substrate transferred from the first transfer module 220 to the standby unit SB_a may wait for a moment. The substrate supplied from the index module 110 to the first transfer module 220 may be seated on the third substrate support 332a of the buffer unit 320 through a first transfer module robot arm 221. The third substrate support 332a may provide a standby space for the substrate loaded into the buffer unit 320. The substrate seated on the third substrate support 332a may be seated on a first substrate support 312a or a second substrate support 312b by a first coating module robot arm 313a or a second coating module robot arm 313b. A coating layer forming process may be performed on the substrate seated on the first substrate support 312a or the second substrate support 312b, and the substrate on which the coating layer forming process has been completed may be seated again on the third substrate support 332a of the buffer unit 320.

The substrate seated on the third substrate support 332a may wait for a moment and may then be seated on the fourth substrate support 332b by a second transfer module exchanger 422 of the second transfer module 420. In this case, a coating layer removing process may not be performed on the fourth substrate support 332b. The substrate waiting on the fourth substrate support 332b may be transferred to first to fourth polishing modules 410a to 410d by the second transfer module robot arm 424 to be subjected to a polishing process.

The substrate on which the polishing process has been completed in the first to fourth polishing modules 410a to 410d may then be transferred back to the second transfer module 420 by the second transfer module robot arm 424. Particularly, the substrate may be seated on the fourth substrate support 332b of the second transfer module 420 by the second transfer module robot arm 424. The fourth substrate support 332b may be located between the second transfer module robot arm 424 and the second transfer module exchanger 422 in the second transfer module 420 to provide a space in which the substrate may wait for a moment or to provide a space in which a process of removing the coating layer formed on the front surface of the substrate may be performed.

The substrate seated on the fourth substrate support 332b may be subjected to a coating layer removing process. Thereafter, the substrate on which the coating layer removing process has been completed may be transferred to the third substrate support 332a of the buffer unit 320 by the second transfer module exchanger 422. The third substrate support 332a may provide a space in which the substrate on which the coating layer removing process has been completed may wait for a moment.

Thereafter, the substrate waiting on the third substrate support 332a may be collected by the first transfer module robot arm 221 of the first transfer module 220 and transferred to the first to sixth cleaning modules 210a to 210f. The first to sixth cleaning modules 210a to 210f may clean off the contaminants remaining on the polished substrate.

Alternatively, in some implementations, the substrate transferred to the fourth substrate support 332b by the second transfer module robot arm 424 may be subjected to a coating layer removing process. The substrate on which the coating layer removing process has been completed on the fourth substrate support 332b may be transferred to the third substrate support 332a of the buffer unit 320 by the second transfer module exchanger 422. The substrate transferred to the third substrate support 332a may wait for a moment and may then be collected by the first transfer module robot arm 221 of the first transfer module 220 and transferred to the first to sixth cleaning modules 210a to 210f. The first to sixth cleaning modules 210a to 210f may clean off the contaminants remaining on the polished substrate.

The substrate polishing apparatus 30a illustrated in FIG. 3B may be substantially the same as or similar to the substrate polishing apparatus 30 illustrated in FIG. 3A, except that the number of polishing modules is different therefrom. Thus, redundant descriptions of the components already mentioned with reference to FIG. 3A will be omitted for conciseness.

The substrate polishing apparatus 30a illustrated in FIG. 3B may include a polishing unit PL_c arranged apart from a cleaning unit CL_b in the first horizontal direction (X direction) with a standby unit SB_a therebetween. Unlike the polishing unit PL_b illustrated in FIG. 3A, the polishing unit PL_c illustrated in FIG. 3B may include two polishing modules, that is, a first polishing module 410a and a second polishing module 410b. The first polishing module 410a and the second polishing module 410b may be located apart from each other in the second horizontal direction (Y direction) with a second transfer module 420 therebetween.

Because only two polishing modules are arranged in the polishing unit PL_c, the length of the substrate polishing apparatus 30a in the first horizontal direction (X direction) may be reduced. Thus, the spatial efficiency of the substrate polishing apparatus 30a may be promoted.

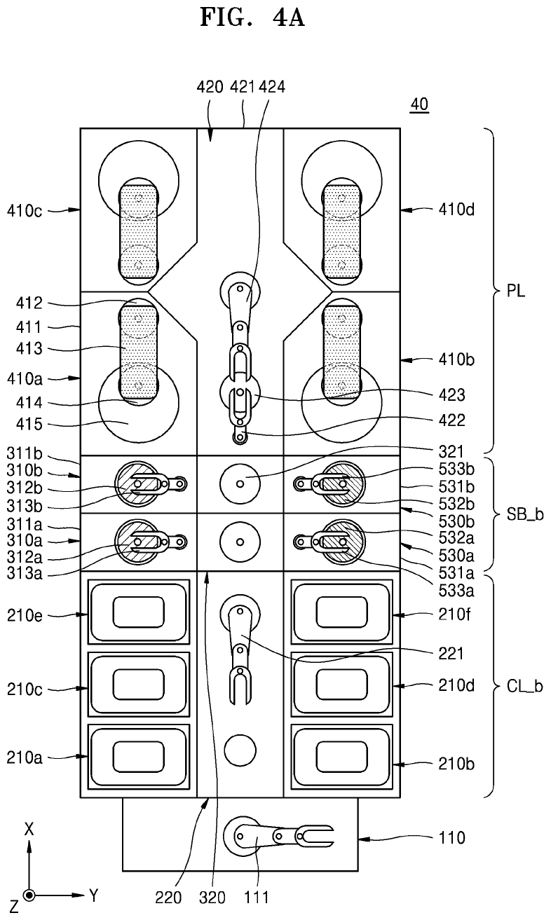

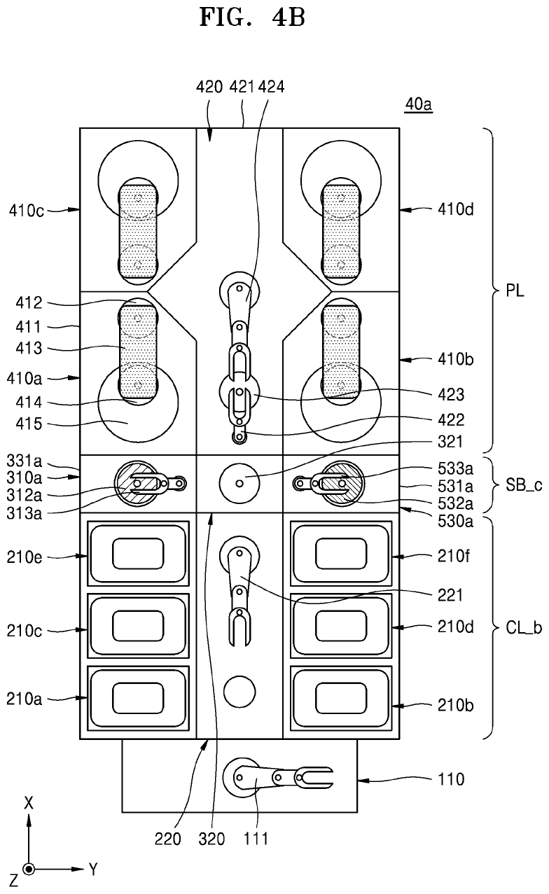

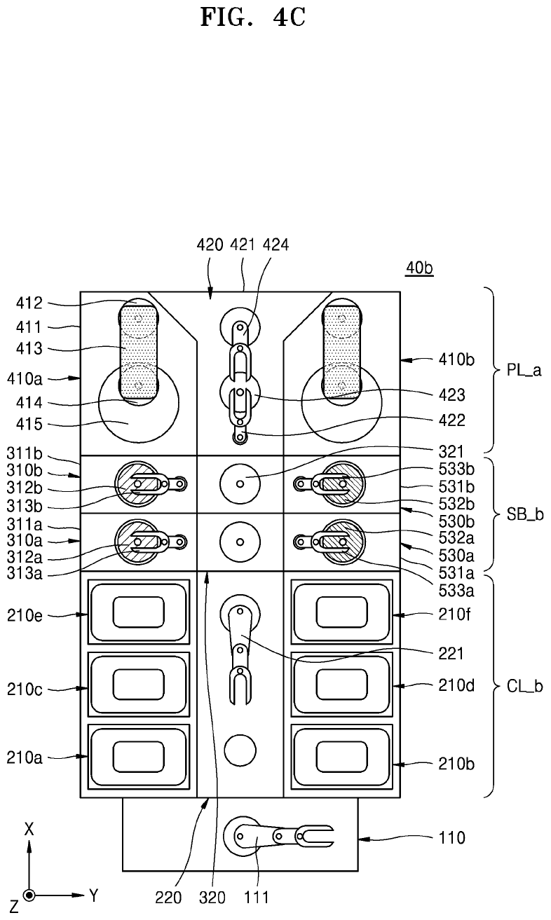

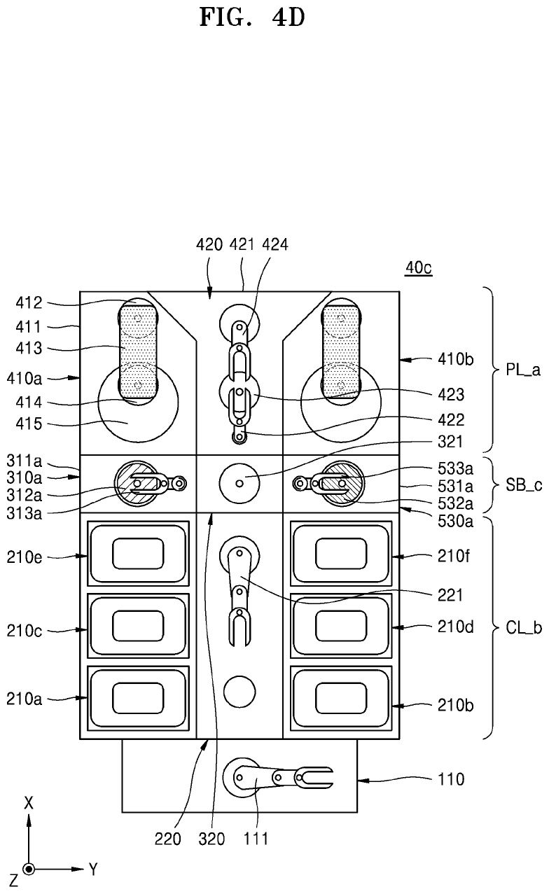

FIG. 4A is a plan view of an example of a substrate polishing apparatus 40, and FIGS. 4B, 4C, and 4D are plan views of an example of a substrate polishing apparatus 40a.

The substrate polishing apparatuses 40 illustrated in FIG. 4A may be substantially the same as or similar to the substrate polishing apparatuses 10 and 10a illustrated in FIGS. 1A and 1B, except that first coating removing module 530a or the second coating removing modules 530b are included in a standby unit SB_c. Thus, redundant descriptions of the components already mentioned with reference to FIGS. 1A and 1B will be omitted or simplified for conciseness.

Referring to FIG. 4A, the substrate polishing apparatus 40 may include an index module 110, a cleaning unit CL_b, a standby unit SB_b, and a polishing unit PL.

The standby unit SB_b arranged between the index module 110 and the polishing unit PL may include a first coating module 310a, a second coating module 310b, a first coating removing module 530a, and a second coating removing module 530b.

The first coating module 310a and the second coating module 310b may be arranged in parallel in the first horizontal direction (X direction), and the first coating removing module 530a and the second coating removing module 530b may also be arranged in parallel in the first horizontal direction (X direction). Also, the first coating module 310a and the first coating removing module 530a may be arranged apart from each other in the second horizontal direction (Y direction) with a buffer unit load cup 321 therebetween, and the second coating module 310b and the second coating removing module 530b may also be arranged apart from each other in the second horizontal direction (Y direction) with a buffer unit load cup 321 therebetween.

In some implementations, the substrate supplied from the index module 110 to a first transfer module 220 may be seated on a buffer unit load cup 321 of a buffer unit 320 by a first transfer module robot arm 221. The buffer unit load cup 321 may provide a standby space for the substrate loaded into the buffer unit 320. The substrate seated on the buffer unit load cup 321 may be seated on a first substrate support 312a of the first coating module 310a or on a second substrate support 312b of the second coating module 310b by a first coating module robot arm 313a or a second coating module robot arm 313b. A coating layer-forming process may be performed on the substrate seated on the first substrate support 312a or the second substrate support 312b, and the substrate on which the coating layer-forming process has been completed may be seated again on the buffer unit load cup 321 of the buffer unit 320 by the first coating module robot arm 313a or the second coating module robot arm 313b.

The substrate seated on the buffer unit load cup 321 may wait for a moment and may then be seated on a second transfer module substrate holder 423 by a second transfer module exchanger 422 of a second transfer module 420. The substrate waiting in the second transfer module substrate holder 423 may then be transferred to first to fourth polishing modules 410a to 410d by a second transfer module robot arm 424 to be subjected to a polishing process.

The substrate on which the polishing process has been completed in the first to fourth polishing modules 410a to 410d may then be transferred back to the second transfer module 420 by the second transfer module robot arm 424. Particularly, the substrate may be seated on the second transfer module substrate holder 423 of the second transfer module 420 by the second transfer module robot arm 424. The second transfer module substrate holder 423 may provide a space in which the substrate may wait before being transferred from the second transfer module 420 to the buffer unit 320.

The second transfer module exchanger 422 may transfer the substrate waiting in the second transfer module substrate holder 423 to the buffer unit load cup 321 of the buffer unit 320. The buffer unit load cup 321 may provide a space in which the substrate may wait before being transferred to the first and second coating removing modules 530a and 530b.

The first coating removing module 530a may include a first coating removing chamber 531a, a third substrate support 532a, and a first coating removing module robot arm 533a. Also, the second coating removing module 530b may include a second coating removing chamber 531b, a fourth substrate support 532b, and a second coating removing module robot arm 533b.

The first coating removing chamber 531a may provide a space for accommodating the third substrate support 532a and the first coating removing module robot arm 533a. Also, the first coating removing chamber 531a may provide a path through which the first coating removing module robot arm 533a may enter/exit to transfer the substrate seated on the buffer unit load cup 321. Likewise, the second coating removing chamber 531b may provide a space for accommodating the fourth substrate support 532b and the second coating removing module robot arm 533b. Also, the second coating removing chamber 531b may provide a path through which the second coating removing module robot arm 533b may enter/exit to transfer the substrate seated on the buffer unit load cup 321.

The first coating removing module robot arm 533a may transfer the substrate seated on the buffer unit load cup 321 to the third substrate support 532a, and the second coating removing module robot arm 533b may transfer the substrate seated on the buffer unit load cup 321 to the fourth substrate support 532b. The substrates seated on the third substrate support 532a and the fourth substrate support 532b may be subjected to a coating layer removing process. Thereafter, the substrate on which the coating layer removing process has been completed may be transferred to the buffer unit load cup 321 of the buffer unit 320 by the first coating removing module robot arm 533a or the second coating removing module robot arm 533b. The buffer unit load cup 321 may provide a space in which the substrate on which the coating layer removing process has been completed may wait for a moment.

Thereafter, the substrate waiting on the buffer unit load cup 321 may be collected by the first transfer module robot arm 221 of the first transfer module 220 and transferred to first to sixth cleaning modules 210a to 210f. The first to sixth cleaning modules 210a to 210f may clean off the contaminants remaining on the polished substrate.

The substrate polishing apparatus 40a illustrated in FIG. 4B may be substantially the same as or similar to the substrate polishing apparatus 40 illustrated in FIG. 4A, except that the number of coating modules and the number of coating removing modules are different therefrom. Thus, redundant descriptions of the components already mentioned with reference to FIG. 4A will be omitted for conciseness.

The substrate polishing apparatus 40a illustrated in FIG. 4B may include a standby unit SB_c arranged between a cleaning unit CL_b and a polishing unit PL in the first horizontal direction (X direction). Unlike the standby unit SB_b illustrated in FIG. 4A, the standby unit SB_c illustrated in FIG. 4B may include one number of the first coating module 310a and one number of the first coating removing module 530a. In the standby unit SB_c, the first coating module 310a and the first coating removing module 530a may be arranged apart from each other in the second horizontal direction (Y direction) with the buffer unit 320 therebetween.

Because only one number of the first coating module 310a and only one number of the first coating removing module 510a are arranged in the standby unit SB_c, the length of the substrate polishing apparatus 40a in the first horizontal direction (X direction) may be reduced. Thus, the spatial efficiency of the substrate polishing apparatus 40a may be promoted.

A substrate polishing apparatus 40b illustrated in FIG. 4C and a substrate polishing apparatus 40c illustrated in FIG. 4D may be substantially the same as or similar to the substrate polishing apparatus 40 illustrated in FIG. 4A and the substrate polishing apparatus 40a illustrated in FIG. 4B, respectively, except that the number of polishing modules is different therefrom. Thus, redundant descriptions of the components already mentioned with reference to FIGS. 4A and 4B will be omitted for conciseness.

The substrate polishing apparatus 40b illustrated in FIG. 4C and the substrate polishing apparatus 40c illustrated in FIG. 4D may include a polishing unit PL_a arranged apart from a cleaning unit CL_b in the first horizontal direction (X direction) with a standby unit SB_c therebetween. Unlike the polishing unit PL illustrated in FIGS. 4A and 4B, the polishing unit PL_a illustrated in FIGS. 4C and 4D may include two polishing modules, that is, a first polishing module 410a and a second polishing module 410b. The first polishing module 410a and the second polishing module 410b may be located apart from each other in the second horizontal direction (Y direction) with a second transfer module 420 therebetween.

Because only two polishing modules are arranged in the polishing unit PL_a, the length of the substrate polishing apparatuses 40b and 40c in the first horizontal direction (X direction) may be reduced. Thus, the spatial efficiency of the substrate polishing apparatuses 40b and 40c may be promoted.

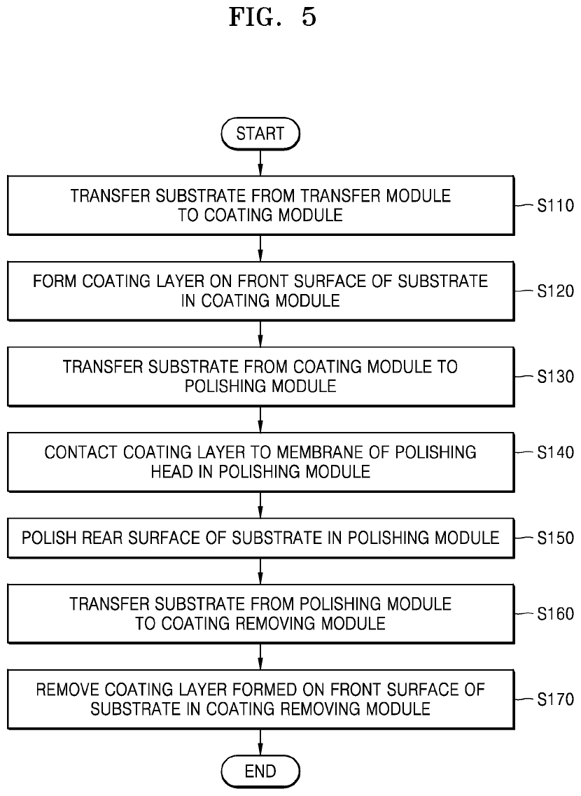

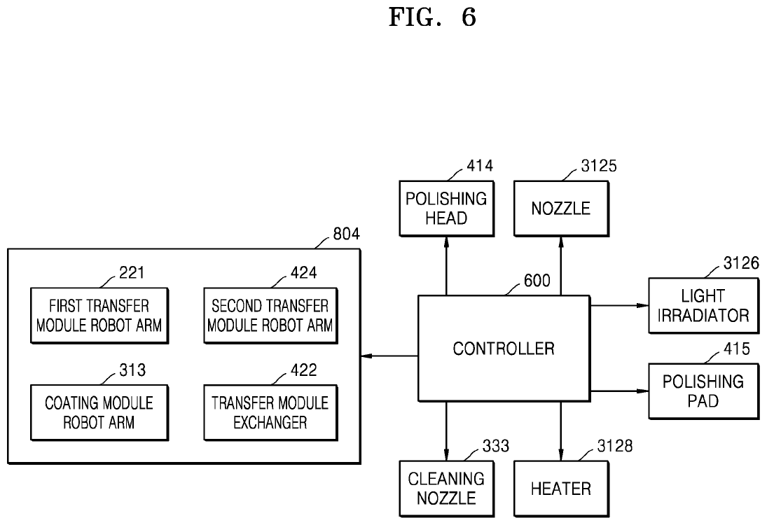

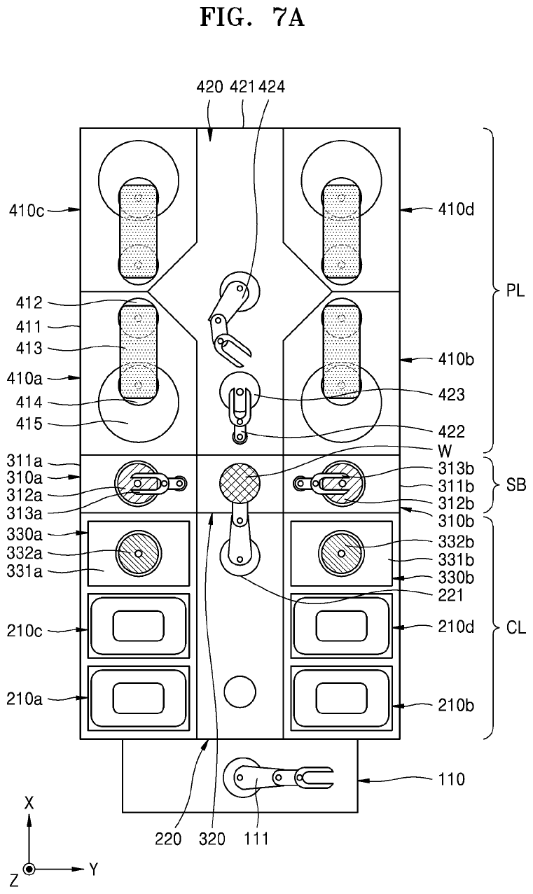

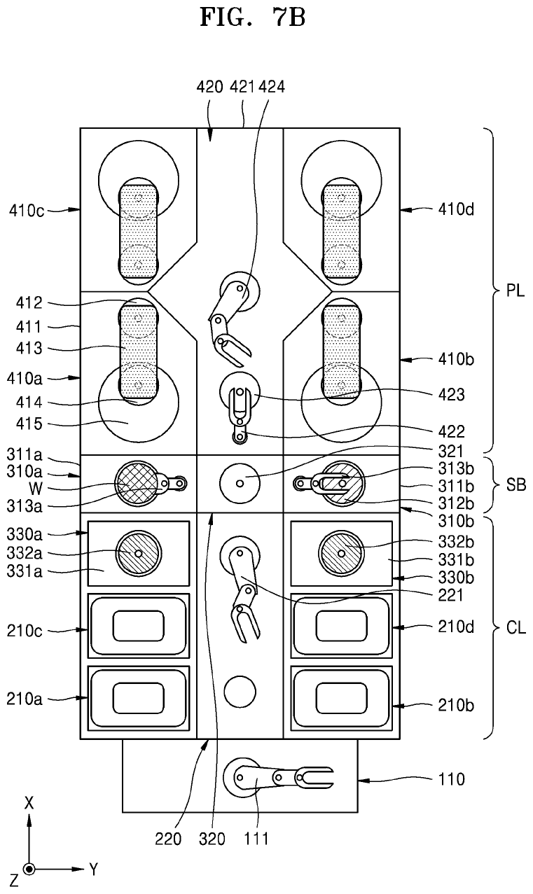

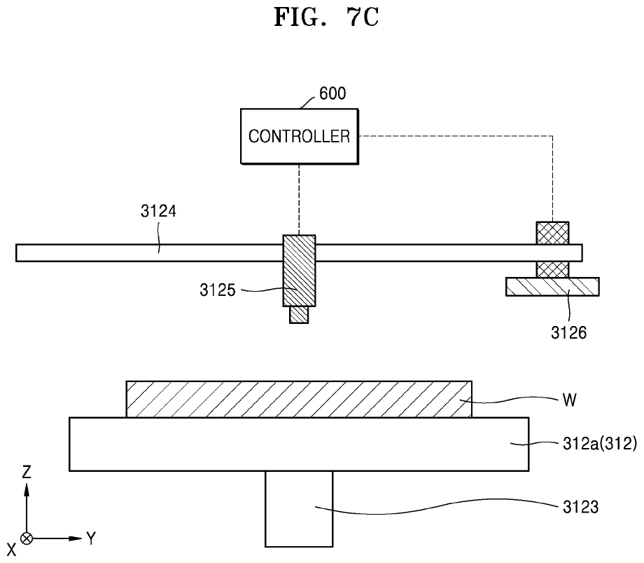

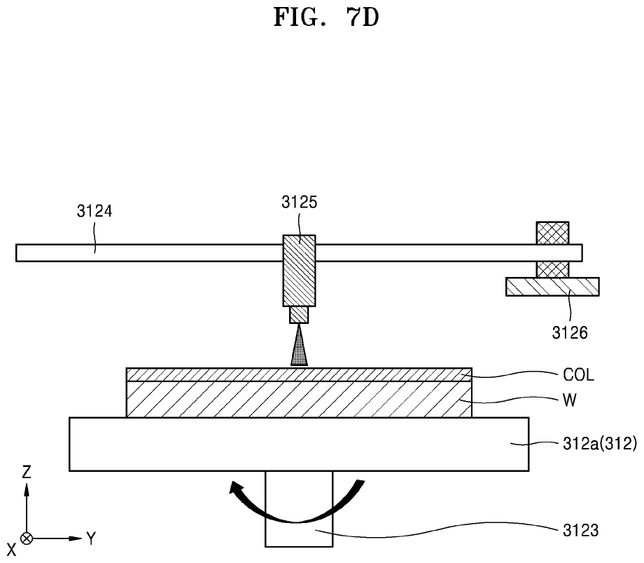

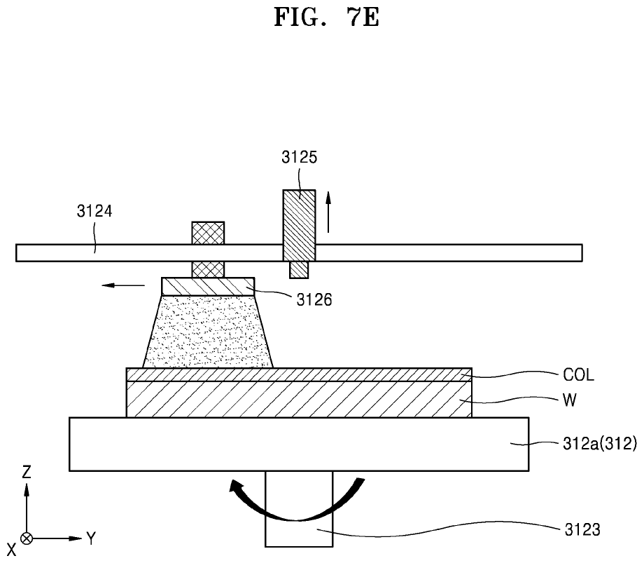

FIG. 5 is a flowchart of an example of a control method of a substrate polishing apparatus 10, and FIG. 6 is a block diagram of an example of a substrate polishing apparatus 10. FIGS. 7A to 7F are cross-sectional views sequentially illustrating some of the sequential processes of an example of a control method of a substrate polishing apparatus 10.

Referring to FIG. 6, a substrate polishing apparatus may include a nozzle 3125, a heater 3128, a light irradiator 3126, a cleaning nozzle 333, a polishing head 414, a polishing pad 415, a controller 600, and a transfer device 804.

The transfer device 804 may refer to a set of devices configured to transfer a substrate in the substrate polishing apparatus, and the transfer device 804 may include a first transfer module robot arm 221, a second transfer module robot arm 424, a coating module robot arm 313, and a transfer module exchanger 422. Herein, the coating module robot arm 313 may refer to, for example, the first and second coating module robot arms 313a and 313b illustrated in FIG. 1, and the transfer module exchanger 422 may refer to, for example, the second transfer module exchanger 422 illustrated in FIG. 1. Also, according to some implementations, the transfer device 804 may also include the first and second coating removing module robot arms 533a and 533b illustrated in FIG. 4A.

The controller 600 may be configured to control an overall operation of the substrate polishing apparatus. The controller 600 may be connected to the transfer device 804, the polishing head 414, the polishing pad 415, the nozzle 3125, the cleaning nozzle 333, the heater 3128, and the light irradiator 3126 and may control at least one of the transfer device 804, the polishing head 414, the polishing pad 415, the nozzle 3125, the cleaning nozzle 333, the heater 3128, and the light irradiator 3126.

In some implementations, the controller 600 may be implemented by hardware, firmware, software, or any combination thereof. For example, the controller 600 may be a computing device such as a workstation computer, a desktop computer, a laptop computer, or a tablet computer. The controller 600 may include a simple controller, a complex processor such as a microprocessor, a central processing unit (CPU), or a graphics processing unit (GPU), a processor implemented by software, and/or dedicated hardware or firmware. The controller 600 may be implemented by, for example, a general-purpose computer or application-specific hardware such as a digital signal processor (DSP), a field programmable gate array (FPGA), and an application-specific Integrated Circuit (ASIC).

In some implementations, the operation of the controller 600 may be implemented as instructions stored on a machine-readable medium that may be read and executed by one or more processors. Here, the machine-readable medium may include any mechanism for storing and/or transmitting information in a form readable by a machine (e.g., a computing device). For example, the machine-readable medium may include read only memory (ROM), random access memory (RAM), a magnetic disk storage medium, an optical storage medium, a flash memory device, electrical, optical, acoustic, or other types of radio signals (e.g., carrier waves, infrared signals, and digital signals), and other suitable signals.

The controller 600 may be implemented by firmware, software, routines, and instructions for operating the substrate polishing apparatus. For example, the controller 600 may receive feedback data, and the controller 600 may generate signals for operating the substrate polishing apparatus and may be implemented by software for performing certain operations.

In some implementations, in order to perform a polishing process of the substrate polishing apparatus, the controller 600 may control the polishing pad 415 and the polishing head 414 to rotate the polishing pad 415 and the polishing head 414.

In some implementations, the controller 600 may control a nozzle configured to spray a coating material onto the front surface of the substrate to form a coating layer on the front surface of the substrate in a coating module. Also, after a coating material is sprayed onto the front surface of the substrate in the coating module, the controller 600 may control the light irradiator 3126 to drive the light irradiator 3126 in the lateral direction to irradiate light onto the coating material in order to cure the coating material.

Also, in some implementations, after a coating material is sprayed onto the front surface of the substrate in the coating module, the controller 600 may control the heater 3128 to drive the heater 3128 in the lateral direction to apply heat to the coating material in order to cure the coating material.

In some implementations, with respect to a substrate on which a polishing process has been completed, in order to remove a coating layer formed on the front surface of the substrate, the controller 600 may control the cleaning nozzle 333 to spray a cleaning solution toward the coating layer.

FIGS. 7A to 7F are cross-sectional views sequentially illustrating some of the sequential processes of an example of a control method of a substrate polishing apparatus 10. The following description will be made with reference to FIG. 5. The substrate polishing apparatus illustrated in FIGS. 7A to 7F may correspond to the substrate polishing apparatus 10 illustrated in FIG. 1A.

Referring to FIGS. 7A and 7B together with FIG. 5, the control method of the substrate polishing apparatus may include operation S110 of transferring a substrate W from a first transfer module 220 to one of a plurality of coating modules 310a and 310b. Herein, as an example, the description will focus on a process of transferring the substrate W from the first transfer module 220 to a first coating module 310a.

First, the first transfer module 220 may be configured to receive the substrate W from an index module robot arm 111 of an index module 110. A path may be formed between the index module 110 and the first transfer module 220, and the index module robot arm 111 may transfer the substrate to the first transfer module 220 through the path. The index module 110 may be provided with a space in which a cassette with substrates W stored therein is located, and the index module robot arm 111 may collect one of the substrates W loaded into the cassette and transfer the collected substrate W to the first transfer module 220.

Thereafter, as illustrated in FIG. 7A, a first transfer module robot arm 221 of the first transfer module 220 may collect the substrate W transferred from the index module robot arm 111 and transfer the collected substrate W to a buffer unit 320 of a standby unit SB. A buffer unit load cup 321 providing a space in which the substrate W may wait for a moment may be arranged in the buffer unit 320 of the standby unit SB. The first transfer module robot arm 221 may seat the substrate W on the buffer unit load cup 321 by passing through a path formed between the first transfer module 220 and the buffer unit 320.

Thereafter, as illustrated in FIG. 7B, the substrate W may be transferred from the buffer unit 320 to the first coating module 310a. Particularly, a first coating module robot arm 313a of the first coating module 310a may collect the substrate W seated on the buffer unit load cup 321, by passing through a path formed between a first coating chamber 311a and the buffer unit 320. After collecting the substrate W seated on the buffer unit load cup 321, the first coating module robot arm 313a may seat the substrate W on a first substrate support 312a arranged in the first coating chamber 311a.

Referring to FIGS. 7C, 7D, 7E, and 7F together with FIG. 5, the control method of the substrate polishing apparatus may include operation S120 of forming a coating layer COL on the front surface of the substrate W in one of the plurality of coating modules 310a and 310b. Herein, as an example, a process of forming the coating layer COL on the front surface of the substrate W in the first coating module 310a will be mainly described.

As illustrated in FIG. 7C, the first coating module 310a may include a first substrate support 312a configured to support the substrate W, a first rotation bar 3123 for driving and supporting the first substrate support 312a to be rotatable in one direction, a driving bar 3124, a nozzle 3125, and a light irradiator 3126.

The substrate W may be seated on the first substrate support 312a such that a front surface of the substrate W faces in the vertical direction (Z direction) and a rear surface of the substrate W opposite to the front surface faces the first substrate support 312a.

The nozzle 3125 and the light irradiator 3126 may be controlled by the controller 600 to move in the lateral direction along the driving bar 3124. Herein, it will be described as an implementation that the nozzle 3125 and the light irradiator 3126 are moved in the second horizontal direction (Y direction) by the controller 600. Also, the nozzle 3125 may be controlled by the controller 600 to descend and/or ascend in the vertical direction (Z direction) at a point of the driving bar 3124 in the lateral direction (X direction and/or Y direction).

The nozzle 3125 may move along the drive bar 3124 so as to be aligned on a center portion of the front surface of the substrate W.

Referring to FIG. 7D, the first substrate support 312a may be configured to be rotated in one direction by the first rotation bar 3123. As the first substrate support 312a rotates, the substrate W seated on the first substrate support 312a may also rotate in one direction. While the substrate W rotates, the nozzle 3125 may be configured to spray a coating material toward the front surface of the substrate W. Even when the nozzle 3125 sprays a coating material toward the center of the front surface of the substrate W, the coating material may spread out in a radial direction due to the centrifugal force according to the rotation of the substrate W. Thus, the coating layer COL may be formed to completely cover the front surface of the substrate W.

Thereafter, referring to FIG. 7E, the nozzle 3125 that has completed spraying the coating material may ascend in the vertical direction (Z direction). Then, the light irradiator 3126 may move in the second horizontal direction (Y direction) along the driving bar 3124 while radiating light. While the light irradiator 3126 moves in the second horizontal direction (Y direction) while radiating light, the first substrate support 312a may rotate continuously in one direction. Thus, even when the light irradiator 3126 moves only in the second horizontal direction (Y direction), because the substrate W seated on the first substrate support 312a rotates continuously in one direction, light may be entirely irradiated onto the coating layer COL. The coating layer COL formed by spraying the coating material onto the front surface of the substrate W may still have the physical properties of a fluid. In this case, when light is irradiated by the light irradiator 3126 onto the coating layer COL, the coating layer COL may be cured.

For example, the light irradiator 3126 may irradiate UV light to the coating layer COL. The light irradiator 3126 may include a plurality of lamps. The light irradiator 3126 may include any one of a halogen lamp, a mercury lamp, a xenon lamp, and an LED lamp. However, the listed types of the light irradiators 3126 are only examples and the present disclosure is not limited thereto.

For example, the coating layer COL may include an inorganic material such as tin oxide. For example, the coating layer COL may include a SnO₂-based resist, a TiO₂-based resist, a ZrO₂-based resist, a Ta₂O₅-based resist, or an HfO₂-based resist. In this case, even when a lithography process and a subsequent process are completed and thus the coating layer COL is removed through a strip process, the inorganic material may remain in the underlayer of the coating layer COL at a concentration of about 1*1011/cm³ or less. When the coating layer COL includes an inorganic material, it may be easy to make the thickness of the coating layer COL thin. The coating layer COL may include a material that causes a photochemical reaction when exposed to light.

In some implementations, the coating layer COL may include a polymer. As an example, the coating layer COL may include a water-soluble polymer. For example, the coating layer COL may include polyethylene glycol, polyacrylamide, polyacrylic acid copolymer, or polyvinyl alcohol.

As another example, the coating layer COL may include a water-insoluble polymer. For example, the coating layer COL may include cellulose ether, acrylic polymer, polyvinyl acetate-based polymer, or a material having a molecular weight of 100 kilodaltons or more among the water-soluble polymers.

As another example, the coating layer COL may include a combination of the water-soluble polymer and the water-insoluble polymer listed above.

Referring to FIG. 7F, after the light irradiator 3126 that has irradiated light to the coating layer COL returns to its original position, the substrate W may be removed from the third substrate support 332a. In this case, the substrate W may be collected by the first coating module robot arm 313a illustrated in FIG. 7B.

FIGS. 8A and 8B are cross-sectional views sequentially illustrating some of the sequential processes of an example of a control method of a substrate polishing apparatus. FIG. 8A may correspond to a portion of the control method of the substrate polishing apparatus corresponding to FIG. 7E.

Referring to FIG. 8A, the first coating module 310a may include a heater 3128 instead of the light irradiator 3126.

The nozzle 3125 that has completed spraying a coating material may ascend in the vertical direction (Z direction). Then, the heater 3128 may move in the second horizontal direction (Y direction) along the driving bar 3124 while radiating heat. While the heater 3128 moves in the second horizontal direction (Y direction) while radiating heat, the first substrate support 312a may rotate continuously in one direction. Thus, even when the heater 3128 moves only in the second horizontal direction (Y direction), because the substrate W seated on the first substrate support 312a rotates continuously in one direction, heat may be entirely applied to the coating layer COL. In this case, when heat is applied by the heater 3128, the coating layer COL may be cured.

For example, the coating layer COL may include polyester/urethane, polyester/epoxy, polyester, acryl/silicon, or any combination thereof. The coating layer COL may include a material that causes a chemical reaction when exposed to heat.

Referring to FIG. 8B, after the heater 3128 that has applied heat to the coating layer COL returns to its original position, the substrate W may be removed from the first substrate support 312a. In this case, the substrate W may be collected by the first coating module robot arm 313a illustrated in FIG. 7B.

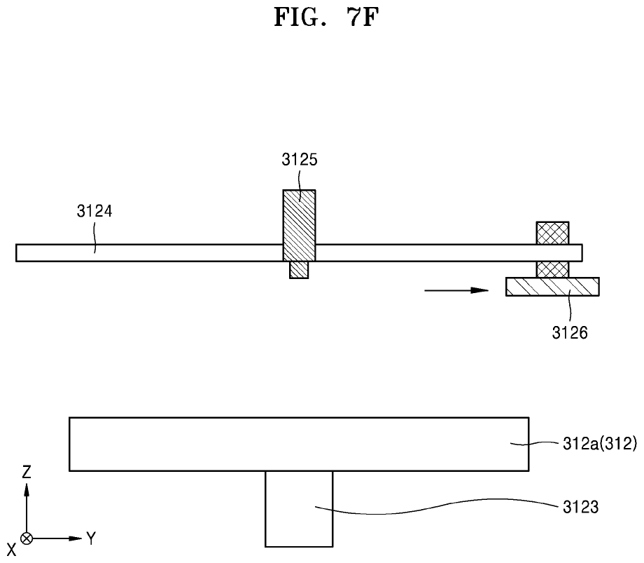

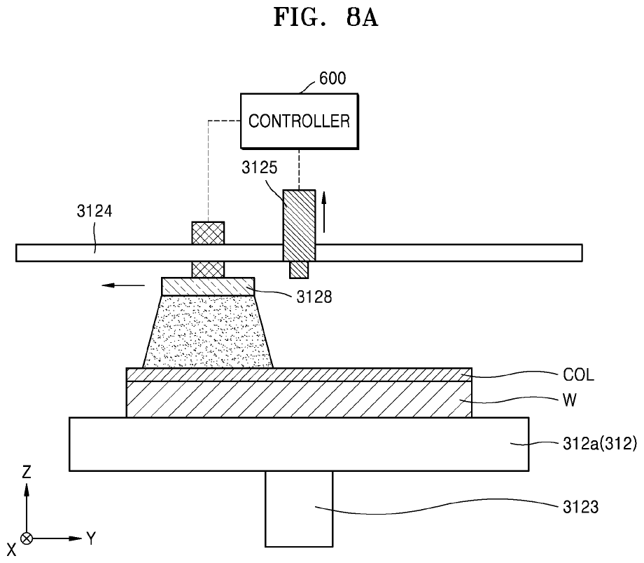

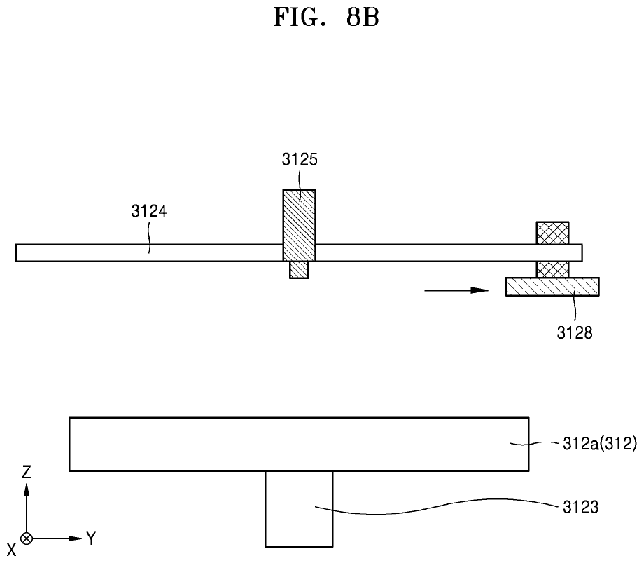

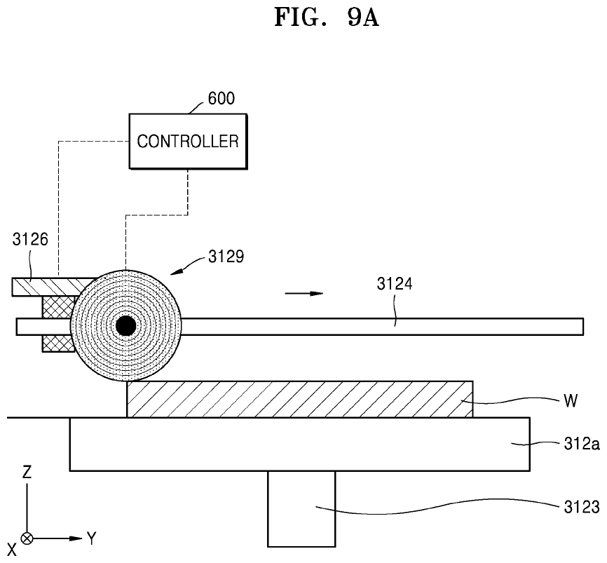

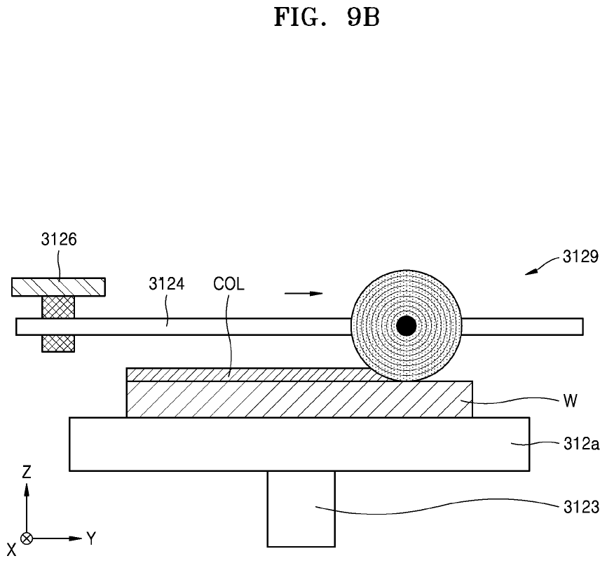

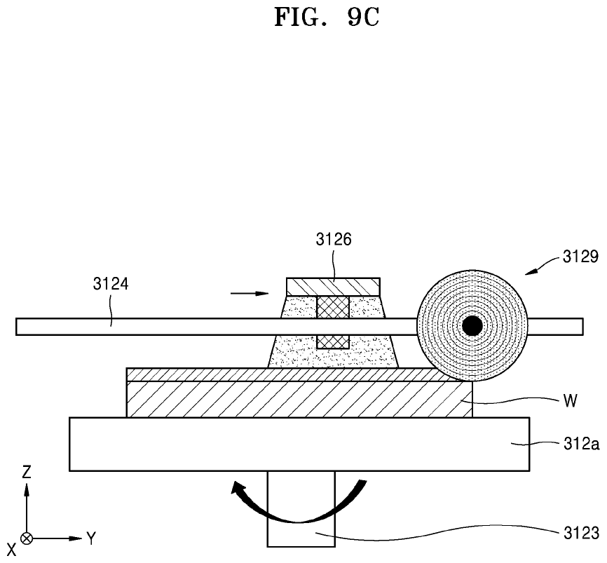

FIGS. 9A to 9D are cross-sectional views sequentially illustrating some of the sequential processes of an example of a control method of a substrate polishing apparatus. Particularly, FIGS. 9A to 9D illustrate different methods of forming the coating layer COL on the front surface of the substrate W.

As illustrated in FIG. 9A, the first coating module 310a may include a first substrate support 312a configured to support the substrate W, a first rotation bar 3123 for driving and supporting the first substrate support 312a to be rotatable in one direction, a driving bar 3124, a nozzle 3125, and a coating film 3129.

In this case, the coating film 3129 may be a roll-shaped film with an adhesive coating layer wound thereon. The coating film 3129 may be configured to move in the second horizontal direction (Y direction) along the driving bar 3124 extending in the second horizontal direction (Y direction). The controller 600 may control the coating film 3129 to move along the driving bar 3124.

Referring to FIG. 9B, the first substrate support 312a may maintain a stationary state without rotating. In this case, the coating film 3129 may move along the driving bar 3124 in the second horizontal direction (Y direction) to attach a coating layer COL wound on the coating film 3129 onto the front surface of the substrate W. In this case, the coating layer COL may include an adhesive material. Then, in some implementations, after the coating film 3129 moves once in the second horizontal direction (Y direction), the first substrate support 312a may move or rotate in the first horizontal direction (X direction). When the first substrate support 312a moves or rotates in the first horizontal direction (X direction), the front surface of the substrate W on which the coating layer COL is not formed may be exposed under the coating film 3129. Thereafter, the coating film 3129 may move again in the second horizontal direction (Y direction) to attach the coating layer COL wound on the coating film 3129 onto the front surface of the substrate W. By repeating this process, the coating layer COL may completely cover the front surface of the substrate W.

Thereafter, referring to FIG. 9C, the light irradiator 3126 may move in the second horizontal direction (Y direction) along the driving bar 3124 while radiating light. While the light irradiator 3126 moves in the second horizontal direction (Y direction) while radiating light, the first substrate support 312a may rotate in one direction. Thus, even when the light irradiator 3126 moves only in the second horizontal direction (Y direction), because the substrate W seated on the first substrate support 312a rotates continuously in one direction, light may be entirely irradiated onto the coating layer COL. When light is irradiated by the light irradiator 3126 to the coating layer COL, the coating layer COL may be cured.

The description of the type of the light irradiator 3126 or the material included in the coating layer COL will be omitted because the description is substantially the same ash the description given above with reference to FIG. 7E.

Referring to FIG. 9D, after the light irradiator 3126 returns to its original position, the substrate W may be removed from the first substrate support 312a. In this case, the substrate W may be collected by the first coating module robot arm 313a illustrated in FIG. 7B.

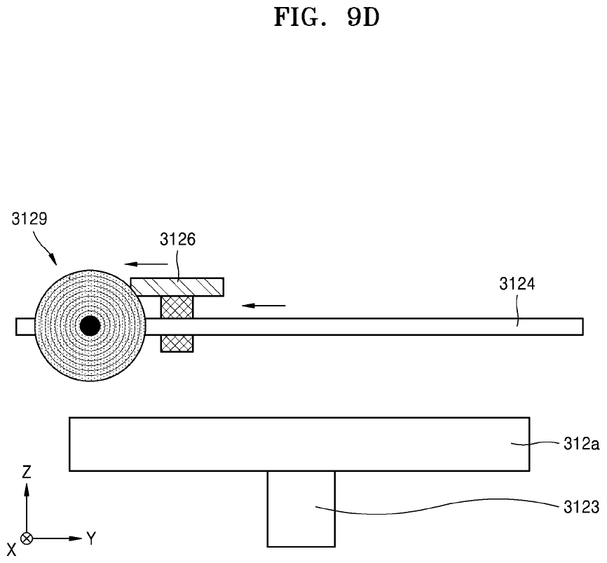

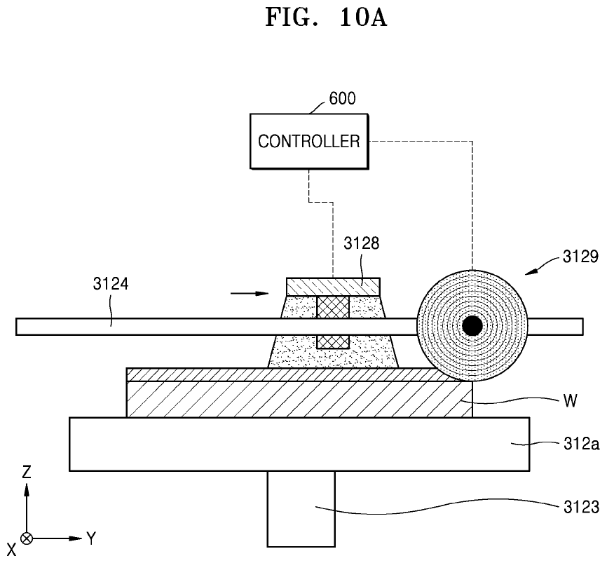

FIGS. 10A and 10B are cross-sectional views sequentially illustrating some of the processes of an example of a control method of a substrate polishing apparatus 10.

Referring to FIG. 10A, the first coating module 310a may include a heater 3128 instead of the light irradiator 3126.

The heater 3128 may move in the second horizontal direction (Y direction) along the driving bar 3124 while radiating heat While the heater 3128 moves in the second horizontal direction (Y direction) while radiating heat, the first substrate support 312a may rotate continuously in one direction. Thus, even when the heater 3128 moves only in the second horizontal direction (Y direction), because the substrate W seated on the first substrate support 312a rotates continuously in one direction, heat may be entirely applied to the coating layer COL. In this case, when heat is applied by the heater 3128, the coating layer COL may be cured.

Because the material included in the coating layer COL is similar to that described above with reference to FIGS. 8A and 8B, redundant descriptions thereof will be omitted for conciseness.

Referring to FIG. 10B, after the coating film 3129 and the heater 3128 that has applied heat to the coating layer COL return to their original positions, the substrate W may be removed from the third substrate support 332a. In this case, the substrate W may be collected by the first coating module robot arm 313a illustrated in FIG. 7B.

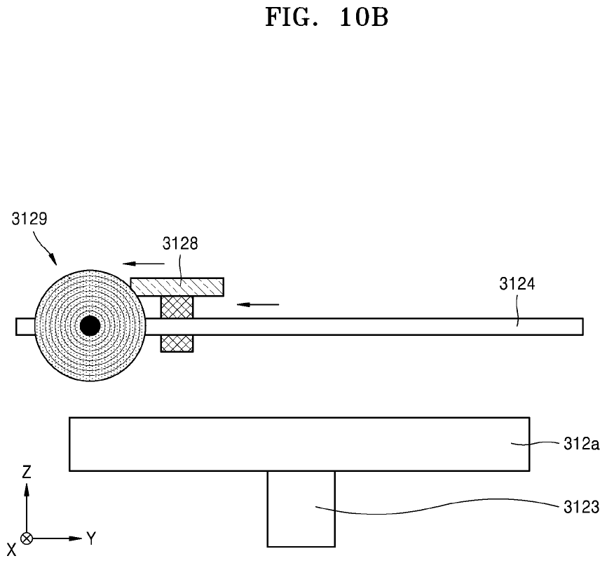

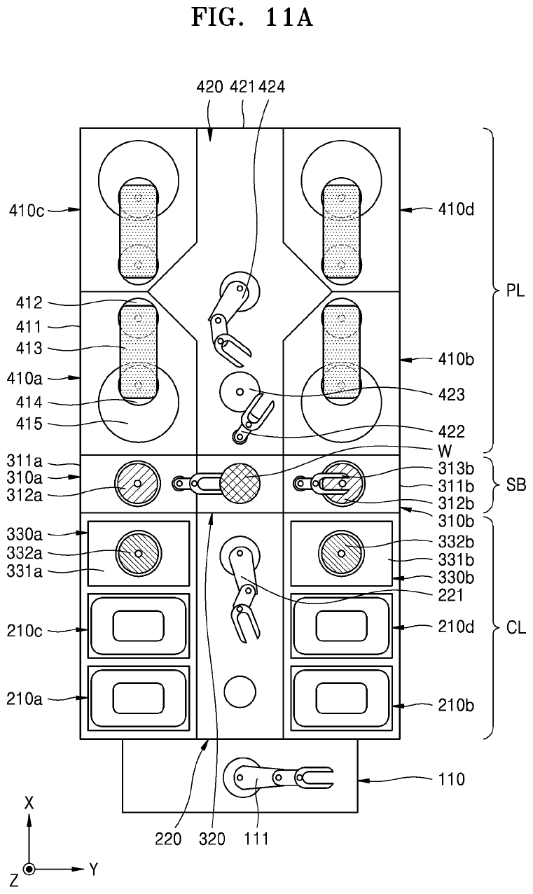

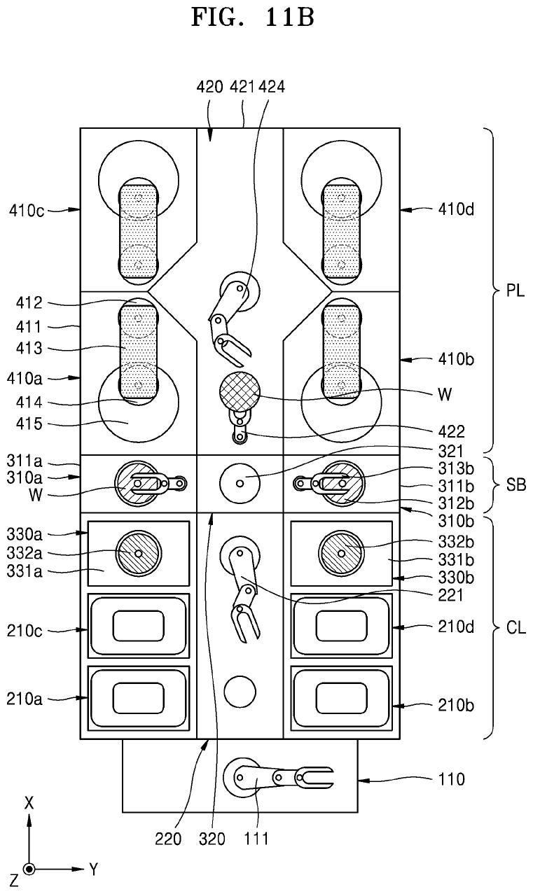

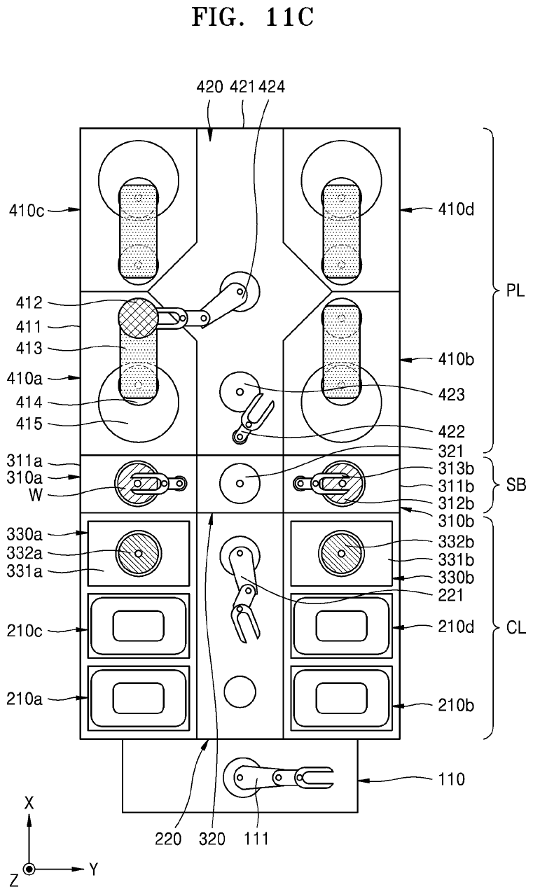

FIGS. 11A to 11C are cross-sectional views sequentially illustrating some of the processes of an example of a control method of a substrate polishing apparatus 10.

Referring to FIGS. 11A, 11B, and 11C together with FIG. 5, the control method of the substrate polishing apparatus may include operation S130 of transferring the substrate W from the coating modules 310a and 310b to one of the plurality of polishing modules 410a to 410d. Herein, a process of transferring the substrate W to the first polishing module 410a among the plurality of polishing modules 410a to 410d will be mainly described as an example.

First, as illustrated in FIG. 11A, the buffer unit 320 may be configured to receive the substrate W from the first coating module robot arm 313a of the first coating module 310a. A path may be formed between the first coating chamber 311a and the buffer unit 320, and the first coating module robot arm 313a may transfer the substrate to the buffer unit 320 through the path. A buffer unit load cup 321 providing a space in which the substrate W may wait for a moment may be arranged in the buffer unit 320, and the first coating module robot arm 313a may seat the substrate W on the buffer unit load cup 321.

Thereafter, as illustrated in FIG. 11B, the second transfer module robot arm 424 of the second transfer module 420 may collect the substrate W seated on the buffer unit load cup 321 and transfer the collected substrate W to the second transfer module 420 of the polishing unit PL. A second transfer module substrate holder 423 providing a space in which the substrate W may wait for a moment may be arranged in the second transfer module 420. The second transfer module robot arm 424 may seat the substrate W on the second transfer module substrate holder 423 by passing through a path formed between the second transfer module 420 and the buffer unit 320.

Thereafter, as illustrated in FIG. 11C, the substrate W may be transferred to the first polishing module 410a of the polishing unit PL. Particularly, the second coating module robot arm 313b of the second coating module 310b may collect the substrate W seated on the second transfer module substrate holder 423. After collecting the substrate W seated on the buffer unit load cup 321, the second coating module robot arm 313b may seat the substrate W on the loading unit 412 arranged in the first polishing module 410a.

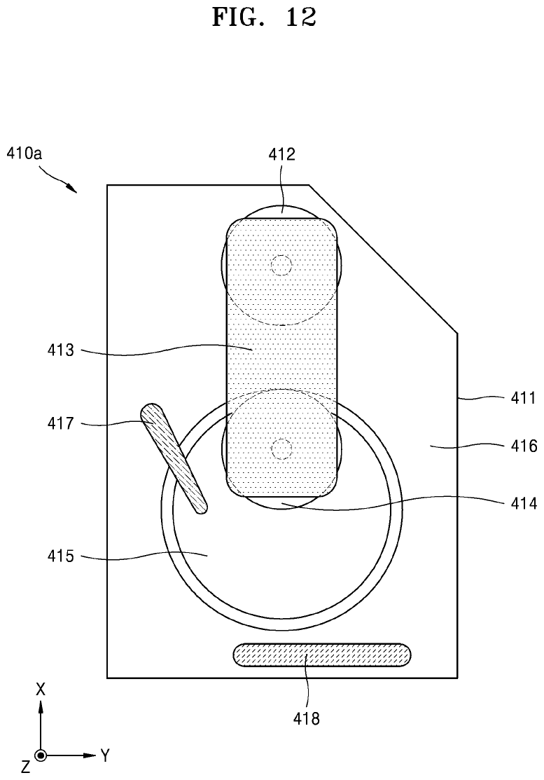

FIG. 12 is a plan view of an example of a polishing module 410a included in a substrate polishing apparatus 10. Herein, a plan view of the first polishing module 410a among the plurality of polishing modules 410a to 410d will be described as an example.

Referring to FIG. 12, the first polishing module 410a may include a polishing chamber 411, a loading unit 412, a polishing head support unit 413, a polishing head 414, a polishing pad 415, a base support 416, a slurry supply device 417, and a conditioner 418.

In the polishing chamber 411, the base support 416 may support the loading unit 412, the polishing head support unit 413, the polishing head 414, the polishing pad 415, the slurry supply device 417, and the conditioner 418.

The polishing pad 415 may be arranged on a processing area 110_a of the base support 416. Also, the polishing pad 415 may be configured to rotate around a rotation axis extending in the vertical direction. Hereinafter, the vertical direction may be defined as a direction perpendicular to the direction in which the upper surface of the base support 416 extends (e.g., the Z direction), and the horizontal direction may be defined as a direction parallel to the direction in which the upper surface of the base support 416 extends (e.g., the direction in which the X-Y plane extends). As the polishing pad 415 rotates on the base support 416, a wafer may be polished by friction between the polishing pad 415 and the wafer.

The substrate seated on the loading unit 412 may be loaded onto the polishing head support unit 413. Also, the substrate loaded on the polishing head support unit 413 may be adsorbed to the polishing head 414.

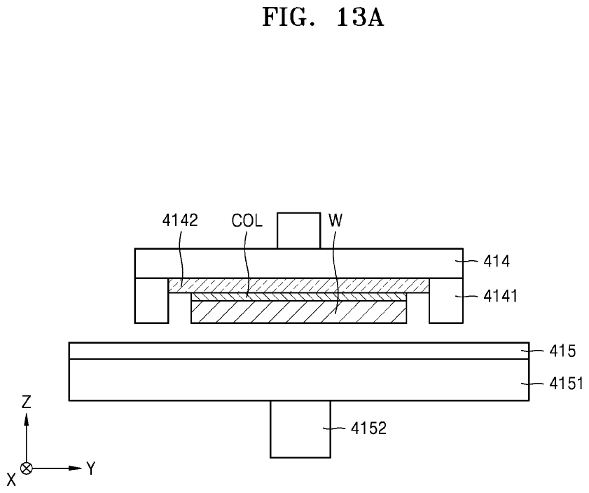

The polishing head 414 may be arranged over the base support 416 and configured to rotate around a rotation axis extending in the vertical direction (Z direction). Accordingly, a retainer ring 4141 (see FIG. 13A) coupled to the polishing head 414 and the substrate may rotate over the base support 416.

In some implementations, the polishing head 414 may be coupled to the polishing head support unit 413 so as to be arranged at a lower vertical level than the polishing head support unit 413. The substrate coupled to the polishing head 414 may rotate on the polishing pad 415 by the rotation of the polishing head 414.

The retainer ring 4141 may be coupled to the lower portion of the polishing head 414. Also, the retainer ring 4141 may support at least a portion of the wafer during the wafer polishing process. For example, the wafer may be supported by the inner surface of the retainer ring 4141.

The slurry supply device 417 may be configured to supply slurry to the upper portion of the polishing pad 415. The slurry may include polishing particles and chemical additives. The polishing particles may perform mechanical polishing of the wafer, and the chemical additives may perform chemical polishing of the wafer.

The conditioner 418 may be configured to apply a pressure to the surface of the polishing pad 415 such that the surface of the polishing pad 415 has a uniform flatness.

FIGS. 13A and 13B are cross-sectional views sequentially illustrating some of the processes of an example of a control method of a substrate polishing apparatus 10.

Referring to FIG. 13A together with FIG. 5, the control method of the substrate polishing apparatus may include operation S140 of contacting the coating layer COL with a membrane 4142 of the polishing head 414 in the polishing module 410a.

Referring to FIG. 13A, the polishing module may include a polishing head 414, a retainer ring 4141, a membrane 4142, a polishing pad 415, a polishing platen 4151, and a second rotation bar 4152.

The retainer ring 4141 may be installed at a lower edge portion of the polishing head 414. The retainer ring 4141 may be attached and assembled to an outer portion of the lower end of the polishing head 414. The retainer ring 4141 may be installed to prevent the detachment of the substrate W contacting the polishing pad 415 and to uniformly supply the polishing slurry during auxiliary polishing.

The membrane 4142 may hold or release the substrate W by vacuum on the lower surface of the polishing head 414. During the polishing, the polishing head 414, the membrane 4142, and the substrate W may rotate in one direction.

The substrate W with the coating layer COL formed on the front surface thereof may be attached onto the membrane 4142. In this case, the membrane 4142 may hold the substrate W by vacuum. However, in some implementations, the substrate W may be held by using an electrostatic force or the like instead of vacuum adsorption. The coating layer COL may be arranged between the membrane 4142 and the substrate W.

Referring to FIG. 13B, the control method of the substrate polishing apparatus 10 may include operation S150 of polishing the rear surface of the substrate W in the polishing module 410a.

In some implementations, the polishing head 414 may descend toward the polishing pad 415 in the vertical direction (Z direction) while rotating in one direction. Simultaneously, the polishing pad 415 may rotate by being connected to the second rotation bar 4152 configured to rotate in a direction opposite to the one direction.

In the process of polishing the rear surface of the substrate W by the polishing pad 415, when the coating layer COL is not arranged between the membrane 4142 and the front surface of the substrate W, particles may occur on the front surface of the substrate W due to the frictional force between the substrate W and the polishing pad 415. The particles may be foreign substances that have fallen from the front surface of the substrate W or foreign substances that have fallen from the membrane 4142. When particles occur on the front surface of the substrate W, the front surface of the substrate W may have an irregular profile due to the friction between the front surface of the substrate W and the membrane 4142. However, as in the present implementation, because a coating layer is arranged between the front surface of the substrate W and the membrane 4142, a situation in which particles may occur on the front surface of the substrate W may be prevented.

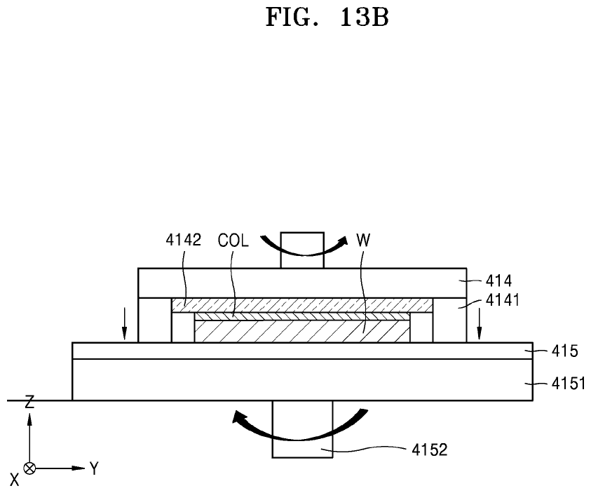

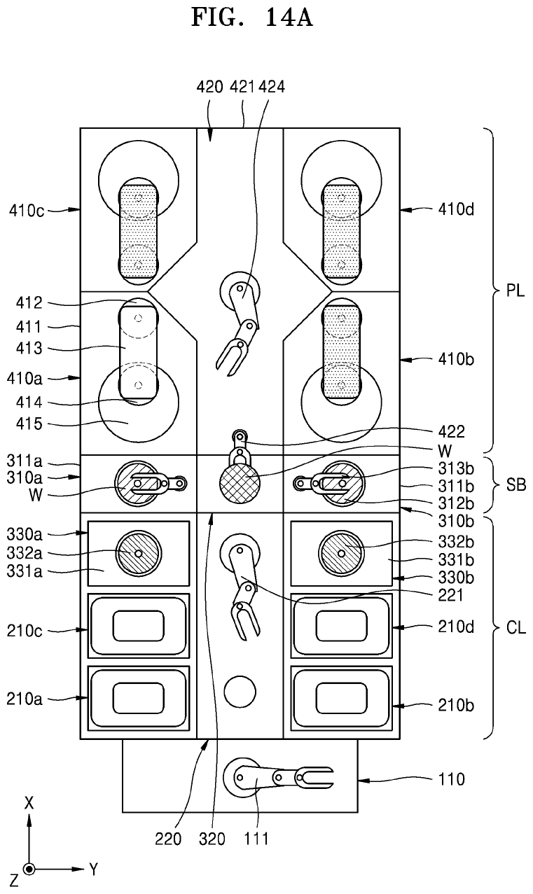

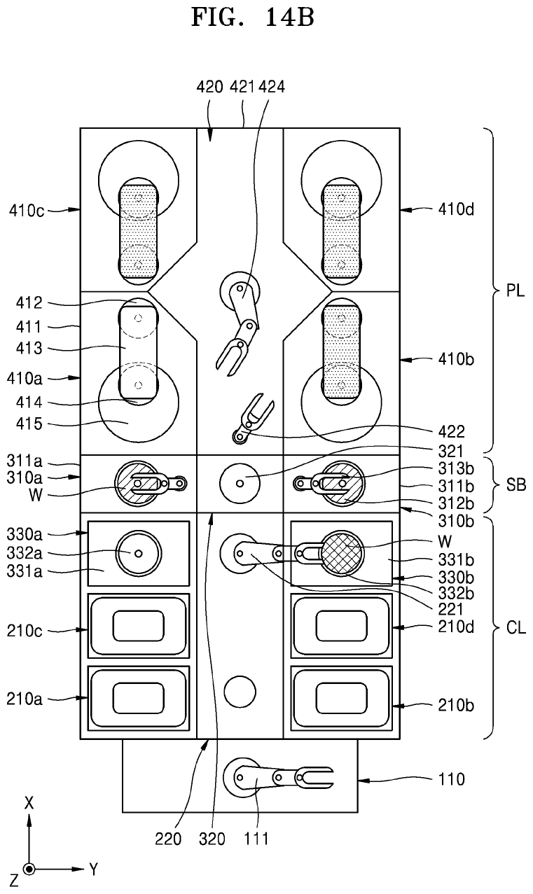

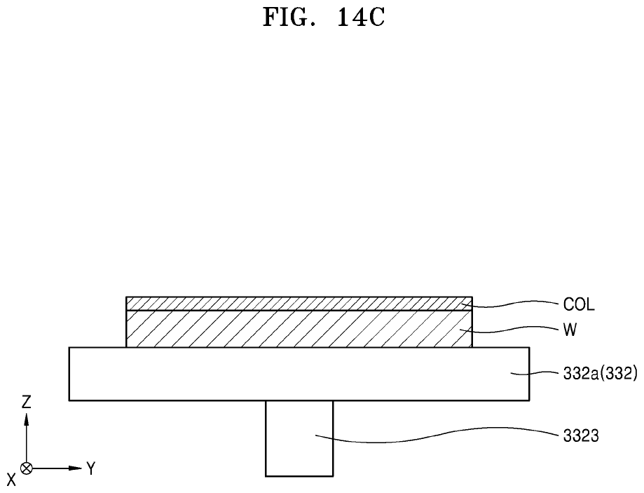

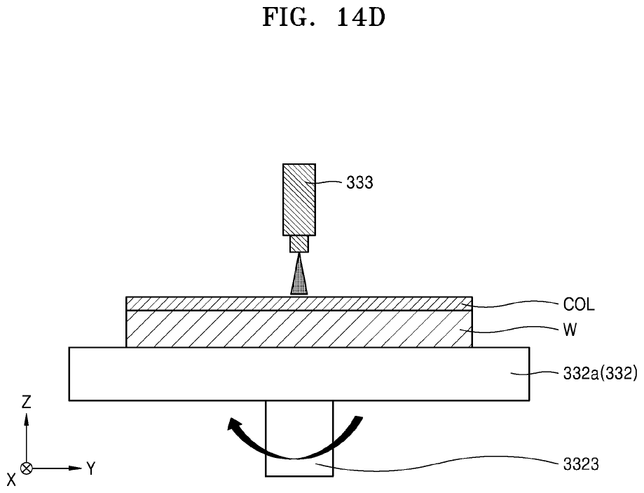

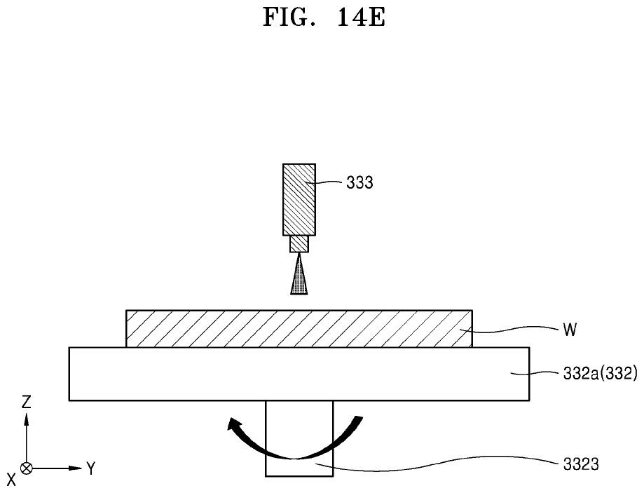

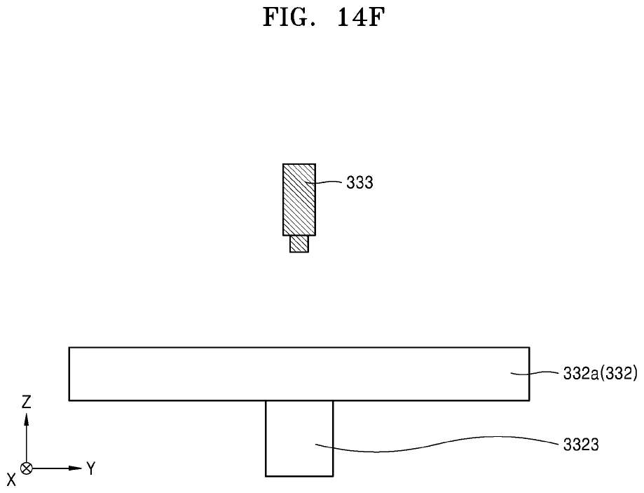

FIGS. 14A to 14F are cross-sectional views sequentially illustrating some of the processes of an example of a control method of a substrate polishing apparatus 10.

Referring to FIGS. 14A and 14B together with FIG. 5, the control method of the substrate polishing apparatus 10 may include operation S160 of transferring the substrate from the polishing module 410a to the first coating removing module 330a. Herein, a process of transferring the substrate to the second coating removing module 330b is illustrated as an example.

As illustrated in FIG. 14A, the buffer unit 320 may be configured to receive the substrate W on which a rear-surface polishing process has been completed from the second transfer module exchanger 422 of the second transfer module 420. A path may be formed between the second transfer chamber 421 and the buffer unit 320, and the second transfer module exchanger 422 may transfer the substrate to the buffer unit 320 through the path. A buffer unit load cup 321 providing a space in which the substrate W may wait for a moment may be arranged in the buffer unit 320, and the second transfer module exchanger 422 may seat, on the buffer unit load cup 321, the substrate W on which the polishing process has been completed.

Thereafter, as illustrated in FIG. 14B, the first transfer module robot arm 221 of the first transfer module 220 may collect the substrate W seated on the buffer unit load cup 321 and transfer the collected substrate W to one of the plurality of coating removing modules 330a and 330b of the cleaning unit CL. Herein, a process of transferring the substrate to the first coating removing module 330a among the plurality of coating removing modules 330a and 330b is illustrated as an example.

A third substrate support 332a supporting the substrate W to perform a coating layer removing process may be arranged in the first coating removing module 330a. The first transfer module robot arm 221 may seat the substrate W on the third substrate support 332a by passing through a path formed between the first transfer module 220 and the first coating removing chamber 331a.

Referring to FIGS. 14C to 14F together with FIG. 5, the control method of the substrate polishing apparatus 10 may include operation S170 of removing the coating layer COL formed on the front surface of the substrate W in the coating removing modules 330a and 330b.

Referring to FIG. 14C, first, the substrate W with the coating layer COL formed on the front surface thereof may be seated on the third substrate support 332a. The substrate W may be seated on the third substrate support 332a such that a front surface of the substrate W faces in the vertical direction (Z direction) and a rear surface of the substrate W opposite to the front surface faces the third substrate support 332a. The third substrate support 332a may be connected to a third rotation bar 3323 configured to be rotatable in one direction.

Referring to FIGS. 14D and 14E, the third substrate support 332a may be configured to rotate in one direction by the third rotation bar 3323. As the third substrate support 332a rotates, the substrate W seated on the third substrate support 332a may also rotate in one direction. The cleaning nozzle 333 may be configured to spray a cleaning solution toward the coating layer COL while the substrate W rotates. Even when the cleaning nozzle 333 sprays a cleaning solution toward the center of the coating layer COL, the cleaning solution may spread out in the radial direction due to the centrifugal force caused by the rotation of the substrate W. Thus, the coating layer COL covering the front surface of the substrate W may be completely removed.

As an example, the cleaning solution may include a liquid capable of being mixed with water. For example, the cleaning solution may include methanol, ethanol, or propanol.

As another example, the cleaning solution may include a liquid incapable of being mixed with water. For example, the cleaning solution may include hexane, benzene, or cyclohexane.

Also, the cleaning solution may include, for example, deionized water (DIW). The cleaning solution may include ammonia (NH₃), sulfuric acid (H₂SO₄), ozone (O₃), hydrofluoric acid (HF), hydrogen peroxide (H₂O₂), or the like.

Referring to FIG. 14F, after spraying of the cleaning solution by the cleaning nozzle 333 is stopped, the substrate W may be removed from the third substrate support 332a. In this case, the substrate W may be collected by the first transfer module robot arm 221 illustrated in FIG. 14A.

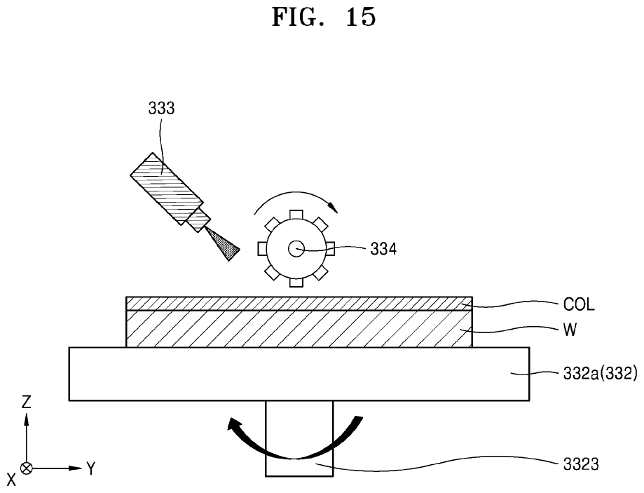

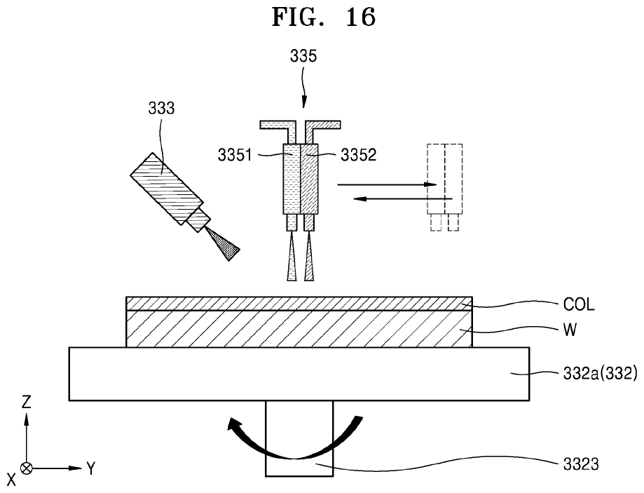

FIGS. 15 and 16 are cross-sectional views sequentially illustrating some of the processes of an example of a control method of a substrate polishing apparatus.

FIGS. 15 and 16 illustrate other examples of a coating removing module configured to remove the coating layer COL formed on the front surface of the substrate W.

Referring to FIG. 15, the coating removing module may further include a roll brush 334. In this case, the roll brush 334 may be aligned to overlap the center of the coating layer COL in the vertical direction (Z direction), and the cleaning nozzle 333 may be arranged on the outer side of the upper portion of the coating layer COL so as not to overlap the roll brush 334 in the vertical direction (Z direction).

As the third substrate support 332a rotates, the substrate W seated on the third substrate support 332a may also rotate in one direction. The cleaning nozzle 333 may spray a cleaning solution toward the coating layer COL while the substrate W rotates. Also, the roll brush 334 may also rotate cylindrically around a rotation axis extending in the lateral direction (e.g., the first horizontal direction (X direction)). Although the roll brush 334 rotates cylindrically, because the substrate W rotates around a rotation axis extending in the vertical direction (Z direction) together with the third substrate support 332a, the entire upper surface of the coating layer COL may cause friction with the roll brush 334. Thus, because the entire coating layer COL causes friction with the roll brush 334 due to the rotation of the third substrate support 332a, the coating layer COL may be easily removed from the front surface of the substrate W.

Referring to FIG. 16, the coating removing module may further include a spray structure 335. In this case, the spray structure 335 may be aligned to overlap the center of the coating layer COL in the vertical direction (Z direction), and the cleaning nozzle 333 may be arranged on the outer side of the upper portion of the coating layer COL so as not to overlap the roll brush 334 in the vertical direction (Z direction).

The spray structure 335 may include a first spray 3351 configured to spray nitrogen (N₂) and a second spray 3352 configured to spray deionized water (DIW) or carbon dioxide (CO₂).

In some implementations, the spray structure 335 may be arranged to overlap the center of the substrate W and then move toward the outer side of the substrate W. The spray structure 335 may move horizontally and reciprocatively between the upper portion of the center of the substrate W and the upper portion of the outer side of the substrate W. Because the spray structure 335 sprays a fluid capable of physically removing the coating layer COL, the spray structure 335 may completely remove the coating layer COL while moving reciprocatively between the upper portion of the center of the substrate W and the upper portion of the outer side of the substrate W over the substrate W that is rotating.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. A substrate polishing apparatus comprising:
a polishing unit comprising a plurality of polishing modules, the plurality of polishing modules defining a first space and being configured to perform a polishing process on a substrate;
a cleaning unit comprising a plurality of cleaning modules, the plurality of cleaning modules defining a second space and being configured to perform a cleaning process on the substrate; and
a standby unit comprising a buffer unit, the buffer unit being positioned between the polishing unit and the cleaning unit in a first horizontal direction, the buffer unit defining a third space that accommodates the substrate;
wherein the standby unit comprises a plurality of coating modules, the plurality of coating modules defining a fourth space and being configured to form a coating layer on a front surface of the substrate, and
wherein each polishing module of the plurality of polishing modules comprises a polishing pad configured to contact a rear surface of the substrate, the rear surface of the substrate being opposite to the front surface of the substrate.

2. The substrate polishing apparatus of claim 1, wherein the cleaning unit comprises a pair of coating removing modules, the pair of coating removing modules defining a fifth space and being configured to remove the coating layer formed on the front surface of the substrate.

3. The substrate polishing apparatus of claim 2, wherein each coating removing module of the pair of coating removing modules comprises:
a substrate support configured to rotate in a first direction and to support the substrate based on contacting the rear surface of the substrate; and
a cleaning nozzle configured to spray a cleaning solution toward the coating layer formed on the front surface of the substrate.

4. The substrate polishing apparatus of claim 3, wherein each coating removing module of the pair of coating removing modules comprises a roll brush configured to rotate and positioned to overlap a center portion of the front surface of the substrate.

5. The substrate polishing apparatus of claim 3, wherein each coating removing module of the pair of coating removing modules comprises a spray structure, the spray structure being located apart from a front surface portion of the substrate and comprising a first spray and a second spray, the first spray being configured to spray nitrogen toward the coating layer, and the second spray being configured to spray carbon dioxide (CO₂) toward the coating layer.

6. The substrate polishing apparatus of claim 1, wherein the plurality of coating modules comprise a first coating module and a second coating module, the second coating module being positioned apart from the first coating module in a second horizontal direction perpendicular to the first horizontal direction, the buffer unit being positioned between the first coating module and the second coating module.

7. The substrate polishing apparatus of claim 1, wherein each coating module of the plurality of coating modules comprises:
a substrate support configured to rotate in a first direction and to support the substrate based on contacting the rear surface of the substrate; and
a nozzle configured to spray a coating material toward the front surface of the substrate.

8. The substrate polishing apparatus of claim 7, wherein each coating module of the plurality of coating modules comprises a light source configured to irradiate light to the coating material sprayed onto the front surface of the substrate.

9. The substrate polishing apparatus of claim 7, wherein each coating module of the plurality of coating modules comprises a heater configured to apply heat to the coating material sprayed onto the front surface of the substrate.

10. The substrate polishing apparatus of claim 1, wherein the buffer unit comprises a coating removing module, the coating removing module defining a fifth space and being configured to remove the coating layer formed on the front surface of the substrate.

11. The substrate polishing apparatus of claim 10, wherein the plurality of coating modules comprise a first coating module and a second coating module, the second coating module being positioned apart from the first coating module in a second horizontal direction perpendicular to the first horizontal direction, and
wherein the coating removing module is positioned between the first coating module and the second coating module.

12. The substrate polishing apparatus of claim 1, wherein the polishing unit comprises a transfer module located between the buffer unit and the plurality of polishing modules, the transfer module being configured to provide a movement path for the substrate between the buffer unit and the plurality of polishing modules, and
wherein the transfer module comprises a coating removing module, the coating removing module defining a fifth space and being configured to remove the coating layer formed on the front surface of the substrate.

13. The substrate polishing apparatus of claim 1, wherein the standby unit comprises a plurality of coating removing modules, the plurality of coating removing modules defining a fifth space and being configured to remove the coating layer formed on the front surface of the substrate, and
wherein the plurality of coating removing modules are positioned to face the plurality of coating modules.

14. A substrate polishing apparatus comprising:
a polishing unit comprising a plurality of polishing modules, the plurality of polishing modules defining a first space and being configured to perform a polishing process on a substrate; and
a cleaning unit comprising a plurality of cleaning modules, the plurality of cleaning modules defining a second space and being configured to perform a cleaning process on the substrate,
wherein the cleaning unit comprises:
a plurality of coating modules, the plurality of coating modules defining a third space and being configured to form a coating layer on a front surface of the substrate, and
a plurality of coating removing modules, the plurality of coating removing modules defining a fourth space and being configured to remove the coating layer formed on the front surface of the substrate, and
wherein each polishing module of the plurality of polishing modules comprises a polishing pad, the polishing pad being configured to contact a rear surface of the substrate, the rear surface being opposite to the front surface.

15. The substrate polishing apparatus of claim 14, wherein the plurality of coating modules and the plurality of coating removing modules are positioned in parallel in a horizontal direction.

16. The substrate polishing apparatus of claim 14, wherein the polishing unit comprises a first transfer module located between the plurality of polishing modules and the cleaning unit, the first transfer module being configured to provide a movement path for the substrate between the plurality of polishing modules and the cleaning unit, and
wherein the plurality of polishing modules comprise a first polishing module and a second polishing module, the second polishing module being positioned apart from the first polishing module, the first transfer module being positioned between the first polishing module and the second polishing module.

17. The substrate polishing apparatus of claim 16, wherein the plurality of polishing modules comprise a third polishing module and a fourth polishing module, the third polishing module being positioned in parallel in a horizontal direction from the first polishing module, and the fourth polishing module being positioned in parallel in the horizontal direction from the second polishing module.

18. The substrate polishing apparatus of claim 14, wherein the plurality of coating modules comprise a first coating module and a second coating module, the second coating module being positioned apart from the first coating module in a horizontal direction, and
wherein the cleaning unit comprises a second transfer module located between the first coating module and the second coating module, the second transfer module being configured to provide a movement path for the substrate between the first coating module and the plurality of polishing modules and between the second coating module and the plurality of polishing modules.

19. A substrate polishing apparatus comprising:
a polishing unit comprising a plurality of polishing modules, the plurality of polishing modules defining a first space and being configured to perform a polishing process on a substrate;
a cleaning unit comprising a plurality of cleaning modules, the plurality of cleaning modules defining a second space and being configured to perform a cleaning process on the substrate; and
a standby unit comprising a buffer unit, the buffer unit being positioned between the polishing unit and the cleaning unit in a first horizontal direction and defining a third space that accommodates the substrate,
wherein the polishing unit comprises a first transfer module located between the buffer unit and the plurality of polishing modules, the first transfer module being configured to provide a movement path for the substrate between the buffer unit and the plurality of polishing modules,
wherein the standby unit comprises a pair of coating modules, the pair of coating modules defining a fourth space and being configured to form a coating layer on a front surface of the substrate, the pair of coating modules being positioned apart from each other in a second horizontal direction perpendicular to the first horizontal direction,
wherein the cleaning unit comprises a pair of coating removing modules, the pair of coating removing modules defining a fifth space and being configured to remove the coating layer formed on the front surface of the substrate, the pair of coating removing modules being positioned apart from each other in the second horizontal direction, and
wherein each polishing module of the plurality of polishing modules comprises a polishing pad, the polishing pad being configured to contact a rear surface of the substrate, the rear surface being opposite to the front surface.

20. The substrate polishing apparatus of claim 19, wherein each coating removing module of the pair of coating removing modules comprises:
a substrate support configured to rotate in a first direction and to support the substrate based on contacting the rear surface of the substrate; and
a cleaning nozzle configured to spray a cleaning solution toward the coating layer formed on the front surface of the substrate.
